(19) United States
(12) Patent Application Publication
(10) Pub. No.: US 2008/0273566 A1
(43) Pub. Date: Nov. 6, 2008

(54) SEMICONDUCTOR LIGHT-EMITTING ELEMENT, METHOD OF PRODUCING SEMICONDUCTOR LIGHT-EMITTING ELEMENT, BACKLIGHT, DISPLAY UNIT, ELECTRONIC DEVICE, AND LIGHT-EMITTING UNIT

(75) Inventors: Ippei Nishinaka, Kanagawa (JP); Goshi Biwa, Kanagawa (JP)

Correspondence Address: BELL, BOYD & LLOYD, LLP, P. O. BOX 1135, CHICAGO, IL, 60690, US

(73) Assignee: SONY CORPORATION, Tokyo (JP)

(21) Appl. No.: 12/051,542

(22) Filed: Mar. 19, 2008

(30) Foreign Application Priority Data
Mar. 20, 2007 (JP) P2007-073636

(51) Int. Cl. H01S 5/34; H01L 33/00

(52) U.S. Cl. 372/45.012; 257/13; 438/47; 257/E33.008

(57) ABSTRACT

A semiconductor light-emitting element includes a nitride-based Group III-V compound semiconductor, wherein the semiconductor light-emitting element has a structure in which an active layer including one or a plurality of well layers is sandwiched between a p-side cladding layer and an n-side cladding layer, and the composition of at least one of the well layers of the active layer is modulated in the direction perpendicular to the thickness direction of the least one of the well layers.

### CROSS REFERENCES TO RELATED APPLICATIONS

The present application claims priority to Japanese Patent Application JP 2007-073636 filed in the Japanese Patent Office on Mar. 20, 2007, the entire contents of which are incorporated herein by reference.

### BACKGROUND

The present application relates to a semiconductor light-emitting element, a method of producing a semiconductor light-emitting element, a backlight, a display unit, an electronic device, and a light-emitting unit. The present application can be preferably applied to, for example, a semiconductor light-emitting element including a gallium nitride-based compound semiconductor, and various devices and units including the semiconductor light-emitting element.

A semiconductor light-emitting element including a gallium nitride-based compound semiconductor can realize emission wavelengths ranging from ultraviolet to infrared by controlling the band-gap energy of an active layer (light-emitting layer) by means of the composition of mixed crystals or the thickness of the active layer. Light-emitting diodes having an emission wavelength ranging from ultraviolet, blue, to green have been commercially available and used for a wide range of applications such as a display, a lighting unit, an inspection unit, and disinfection. A laser diode (semiconductor laser) having an emission wavelength of blue-violet has been also developed and used as a pickup light source for writing or reading in large-capacity optical disks.

Such a semiconductor light-emitting element including a gallium nitride-based compound semiconductor generally includes an active layer having a multiquantum well structure prepared by alternately stacking well layers and barrier layers. Various techniques have been proposed to improve the luminous efficiency of the active layer having a multiquantum well structure. Examples thereof include techniques in which the number of well layers is specified (see Japanese Unexamined Patent Application Publication Nos. 10-261838 and 10-256657), techniques in which the compositions of mixed crystals of well layers and barrier layers are specified (see Japanese Unexamined Patent Application Publication Nos. 2000-261106 and 2000-91629), and a technique in which the emission intensity ratio of a plurality of emission peaks is controlled by introducing a multiquantum barrier structure to barrier layers provided between well layers having emission wavelengths different from each other (see Japanese Unexamined Patent Application Publication No. 2002-368268). In the active layer having a multiquantum well structure used in these semiconductor light-emitting elements, all barrier layers have the same composition, the same thickness, and the same structure.

A technique in which an active layer having a multiquantum well structure includes barrier layers having different compositions has also been proposed (see Japanese Unexamined Patent Application Publication No. 2004-179428, in particular, see claim 3 and FIGS. 4 and 5). According to this technique, holes and electrons can be intentionally concentrated on a well layer disposed near a p-type cladding layer.

Furthermore, in order to solve a problem of uneven recombination in a multilayer-well active layer caused by a difference between the electron mobility and the hole mobility, the use of an active layer having an asymmetric structure has been proposed, though this technique is not limited to a semiconductor light-emitting element including a gallium nitride-based compound semiconductor (see, for example, PCT Japanese Translation Patent Publication No. 2003-520453 (document '453)). Document '453 discloses various examples in which the composition and the thickness of well layers, and the composition and the thickness of barrier layers are varied in an active layer and describes that “such that a barrier layer located nearer to an n-type lower sealing layer 34 has a thickness larger than a barrier layer located farther from the n-type lower sealing layer” (paragraph 0032 in document '453). However, regarding a semiconductor light-emitting element including a gallium nitride-based compound semiconductor, document '453 only describes calculation examples in which the compositions of the barrier layers are varied stepwise and does not specifically specify the asymmetry regarding the thicknesses of the barrier layers with which the luminous efficiency can be improved. In addition, document '453 neither discloses nor suggests a modulation of the compositions of the well layers therein.

In a semiconductor light-emitting element including a gallium nitride-based compound semiconductor, it is known that when the indium (In) content of a well layer is increased in the preparation of a multiquantum well structure including a gallium nitride-based compound semiconductor, in theory, an emission peak is shifted to the longer wavelength side, and the luminous efficiency is decreased at the same time. Accordingly, problems occur when a plurality of semiconductor light-emitting elements having different emission wavelengths are used in combination.

### SUMMARY

It is desirable to provide a semiconductor light-emitting element in which even when the emission wavelength is increased, a decrease in the luminous efficiency can be easily prevented by a method different from a method in the related art in the case where a gallium nitride-based compound semiconductor, more generally, a nitride-based Group III-V compound semiconductor is used for a semiconductor light-emitting element. It is desirable to provide a method of producing a semiconductor light-emitting element by which such a semiconductor light-emitting element can be easily produced.

It is desirable to provide a semiconductor light-emitting element in which the luminous efficiency can be easily controlled, and a method of producing a semiconductor light-emitting element by which such a semiconductor light-emitting element can be easily produced.

It is desirable to provide a backlight, a display unit, an electronic device, and a light-emitting unit including the above-mentioned semiconductor light-emitting element.

The above-mentioned semiconductor light-emitting elements, the methods of producing a semiconductor light-emitting element, the backlight, the display unit, the electronic device, the light-emitting unit, and further features of embodiments will become apparent from a description below with reference to the attached drawings.

As a result of intensive studies, the present inventors have experimentally verified that, in a semiconductor light-emitting element including a nitride-based Group III-V compound semiconductor, when the composition of a well layer of an active layer having a multiquantum well structure is varied, the luminous efficiency is decreased, and found a specific method for preventing the decrease in the luminous efficiency due to the above phenomenon. The outline thereof will now be described.

A GaN-based light-emitting diode shown in FIG. 1 was prepared. More specifically, a sapphire substrate 11 having a C-plane as a principal surface was cleaned in hydrogen carrier gas at 1,050° C. for 10 minutes. The temperature was then decreased to 500° C., and ammonia, which is a nitrogen source, was supplied. In addition, trimethylgallium (TMG), which is a gallium source, was supplied by switching valves, and a low-temperature GaN buffer layer 12 having a thickness of 30 nm was grown by a metalorganic chemical vapor deposition (MOCVD) method. The temperature was increased to 1,020° C. in a state in which the supply of TMG was temporarily stopped, and the supply of TMG was then started again, thus growing an undoped GaN layer 13 having a thickness of 1 μm. Subsequently, supply of silane (SiH₄), which is a silicon source, was started, thus growing a Si-doped n-type GaN layer 14 having a thickness of 3 μm. The doping concentration of Si in this n-type GaN layer 14 was 5×10¹⁸/cm³. The supply of SiH₄ was then stopped, and ammonia and TMG were supplied to grow an undoped GaN layer 15 having a thickness of 5 nm. Next, the supply of TMG and SiH₄ was stopped, the carrier gas was switched from hydrogen to nitrogen, and the temperature was decreased to 750° C. Trimethylindium (TMI) was then supplied as an indium source by switching valves while triethylgallium (TEG) was supplied as a gallium source. Thus, as shown in FIGS. 1 and 2, well layers each composed of an InGaN sublayer 16a having a thickness of 3 nm and barrier layers each composed of a GaN sublayer 16b having a thickness of 15 nm were alternately grown to form an active layer 16 having an InGaN/GaN multiquantum well structure. This active layer 16 had a multiquantum well structure including nine wells in which nine well layers were separated by eight barrier layers. The indium (In) content of the InGaN sublayer 16a was 0.23, which corresponded to an emission wavelength of 515 nm. Next, the temperature was increased to 800° C. while an undoped GaN layer 17 having a thickness of 10 nm was grown on the active layer 16. Supply of trimethylaluminum (TMA), which is an aluminum source, and biscyclopentadienyl magnesium (Cp₂Mg), which is a magnesium source, was started, thus growing a Mg-doped p-type AlGaN layer 18 having an aluminum content of 0.15 and a thickness of 20 nm. The doping concentration of Mg in this p-type AlGaN layer 18 was 5×10¹⁹/cm³. Subsequently, the supply of TEG, TMA, and Cp₂Mg was stopped, the carrier gas was switched from nitrogen to hydrogen, and the temperature was increased to 850° C. The supply of TMG and Cp₂Mg was started, thus growing a Mg-doped p-type GaN layer 19 having a thickness of 100 nm. The doping concentration of Mg in this p-type GaN layer 19 was 5×10¹⁹/cm³. The supply of TMG and Cp₂Mg was then stopped, the temperature was decreased, and the supply of ammonia was stopped at 600° C. The temperature was decreased to room temperature to finish the growth of the crystals. Herein, the growth temperature of growth performed after the growth of the active layer 16 was set to a temperature lower than 1,350−0.75λ (° C.), preferably 1,250−0.75λ (° C.) wherein λ represents the emission wavelength (nm). This is an effective technique particularly in a GaN-based semiconductor light-emitting element having a long emission wavelength (see, for example, Japanese Unexamined Patent Application Publication No. 2002-319702).

The sapphire substrate 11 obtained after the crystal growth as described above was annealed in a nitrogen atmosphere at 800° C. for 10 minutes to activate Mg doped in the p-type AlGaN layer 18 and the p-type GaN layer 19.

Subsequently, as in the production process of a normal light-emitting diode ranging from a wafer process to a chip-forming process, more specifically, photolithography, etching, metal evaporation, and the like are performed, the resulting substrate is separated into chips by dicing, and resin molding and packaging are then performed. Consequently, various types of GaN-based light-emitting diodes, such as a shell-type light-emitting diode and a surface-mounted light-emitting diode, can be produced. Here, for the purpose of evaluation and simplification, a GaN-based light-emitting diode shown in FIG. 3 was prepared. More specifically, as shown in FIG. 3, the n-type GaN layer 14 was exposed by lithography and etching, a p-side electrode 20 made of Ag/Ni was formed on the p-type GaN layer 19, and an n-side electrode 21 made of Ti/Al was formed on the n-type GaN layer 14. Probes 22 and 23 were placed on the p-side electrode 20 and the n-side electrode 21, respectively, using a prober, and then energized, thus detecting light 24 emitted from the bottom surface of the sapphire substrate 11 with a detector 25. In FIG. 3, the low-temperature GaN buffer layer 12, the undoped GaN layer 13, the undoped GaN layer 15, and the undoped GaN layer 17 are not shown.

According to the measurement results of the above GaN-based light-emitting diode, the emission peak wavelength was 515 nm and the luminous efficiency was 180 mW/A at a drive current density of 60 A/cm². Note that if this light-emitting diode is mounted on a mount with a high reflectance and molded with a resin with a high refractive index as in the case of a commercially available light-emitting diode, a luminous efficiency about at least double the above value can be obtained by a total luminous flux measurement.

Similarly, GaN-based light-emitting diodes having different In contents of the InGaN sublayers 16a functioning as the well layers were prepared, and an electroluminescence measurement was performed. In this measurement, excitation was performed by irradiating a continuous-wave (CW) laser beam emitted from a Kr laser with an output of 3 mW at a wavelength of 407 nm through a lens having a magnification of ×5. The excitation intensity was constant. FIG. 4 shows the relationship between the emission wavelength and the emission intensity. In FIG. 4, the horizontal axis represents the emission wavelength, and the vertical axis represents the emission intensity of light corresponding to the emission wavelength with arbitrary units (A.U.). As is apparent from FIG. 4, the rate of decrease in the luminous efficiency increases from an In content of about 0.23 (emission wavelength: 515 nm).

The cause of such a decrease in the luminous efficiency with an increase in the In content of the InGaN sublayer 16a functioning as a well layer can be described with the following model. When the In content of the InGaN sublayer 16a is increased, the piezoelectric field generated from the difference between a lattice constant of GaN and a lattice constant of InN is also increased. As a result, a difference in the electric potential is generated in the active layer 16 in the thickness direction thereof. As the In content of the InGaN sublayer 16a increases, this electric potential difference also increases.

FIGS. 5A to 5C schematically show the valence band and the conduction band of the InGaN sublayer 16a and the vicinity thereof in the case of an emission wavelength of ultraviolet light, an emission wavelength of blue light, and an emission wavelength of green light, respectively. In FIGS. 5A to 5C, Eᵥ represents an energy at the top of the valence band, and E_{c} represents an energy at the bottom of the conduction band. In the case shown in FIG. 5A, the electric potential difference generated in the active layer 16 is small, and the piezoelectric field E_{piezo} is E_{piezo}≦1 MV/cm or less. Therefore, the valence band and the conduction band of the InGaN sublayer 16a are substantially flat, and the position of the wave function distribution of electrons is substantially the same as the position of the wave function distribution of holes, which are ideal wave function distributions. In contrast, in the case shown in FIG. 5B in which the In content of the InGaN sublayer 16a is larger than that of the case shown in FIG. 5A, the electric potential difference generated in the active layer 16 is increased, and the piezoelectric field E_{piezo} is in the range of about 2.2 to 2.4 MV/cm. Therefore, the position of the wave function distribution of electrons is considerably shifted from the position of the wave function distribution of holes, which causes a decrease in the luminous efficiency. In the case shown in FIG. 5C in which the In content of the InGaN sublayer 16a is further increased, the piezoelectric field E_{piezo} is in the range of about 3.1 to 3.4 M/cm. Therefore, the position of the wave function distribution of electrons is further considerably shifted from the position of the wave function distribution of holes, and thus the luminous efficiency is further decreased. That is, when the In content of the InGaN sublayer 16a is increased in order to realize a long emission wavelength, the position of the wave function distribution of electrons is far from the position of the wave function distribution of holes. Accordingly, it is believed that a decrease in the luminous efficiency occurs with an increase in the emission wavelength, as shown in FIG. 4.

To prevent this phenomenon, it is believed that the position of the wave function distribution of electrons can be made close to the position of the wave function distribution of holes by utilizing the difference between the effective mass of an electron and the effective mass of a hole. The effective mass of an electron in a GaN-based compound semiconductor is 0.19 m₀, and the effective mass of a hole in the GaN-based compound semiconductor is 1.66 m₀ (wherein m₀ represents the rest mass of an electron). Accordingly, the effective mass of an electron is about ⅛ of the effective mass of a hole. More specifically, the band line-up of the InGaN sublayer 16a functioning as a well layer is controlled by varying the In content, and thus the band gap energy of the InGaN sublayer 16a at the p-layer side is controlled to be higher or lower than that of the InGaN sublayer 16a at the n-layer side. FIGS. 6A and 7A schematically show this idea. FIGS. 6B and 7B show the distributions of the In content of the InGaN sublayer 16a shown in FIGS. 6A and 7A, respectively. In the example shown in FIG. 6A (hereinafter referred to as “Type A”), by gradually increasing the In content during the growth of the InGaN sublayer 16a, the electric potential difference between the valence band and the conduction band at the p-layer side is made smaller than that at the n-layer side. In the example shown in FIG. 7A (hereinafter referred to as “Type B”), by gradually decreasing the In content during the growth of the InGaN sublayer 16a, the electric potential difference between the valence band and the conduction band at the p-layer side is made larger than that at the n-layer side. In FIGS. 6A and 7A, the broken lines show the case where the In content is constant.

Comparing the InGaN sublayer 16a of the active layer 16 of Type A with that of Type B described above, from the standpoint of the electric potential difference between the valence band and the conduction band in the active layer 16, it is believe that, in the case of Type A, both the wave function distribution of electrons and that of holes are shifted to the p-layer side, and in the case of Type B, both the wave function distribution of electrons and that of holes are shifted to the n-layer side. In this case, considering the effective masses of an electron and a hole, it is believed that since the effective mass of an electron is significantly smaller than the effective mass of a hole, the wave function distribution of electrons easily moves. As described above, in a GaN-based compound semiconductor, the effective mass of an electron is about ⅛ of the effective mass of a hole. Therefore, FIGS. 6A and 7A show states of wave function distribution in the case where a shift of the wave function distribution of holes is ignored.

Consequently, when the In content is gradually decreased in the InGaN sublayer 16a, as in Type B, the shift between the wave function distribution of electrons and the wave function distribution of holes in the InGaN sublayer 16a is decreased, as compared with the case of Type A. As a result, it is believed that the luminous efficiency is increased.

On the other hand, by gradually increasing the In content in the InGaN sublayer 16a, the shift between the wave function distribution of electrons and the wave function distribution of holes in the InGaN sublayer 16a is increased. As a result, it is believed that the luminous efficiency can be decreased.

Accordingly, the luminous efficiency can be controlled by modulating the In content of the InGaN sublayer 16a in the direction perpendicular to the thickness direction of the InGaN sublayer 16a.

In other words, by decreasing or increasing the In content of the InGaN sublayer 16a in the direction of the piezoelectric field E_{piezo}, the luminous efficiency can be controlled.

A description has been made of a case where the well layer in the active layer having a multiquantum well structure is an InGaN sublayer. However, the above phenomenon can also apply to a case where the well layer has a composition different from that of the InGaN sublayer.

The present application has been conceived as a result of a further study based on the above study made by the present inventors.

More specifically, according to an embodiment, a semiconductor light-emitting element includes a nitride-based Group III-V compound semiconductor, wherein the semiconductor light-emitting element has a structure in which an active layer including one or a plurality of well layers is sandwiched between a p-side cladding layer and an n-side cladding layer, and the composition of at least one of the well layers of the active layer is modulated in the direction perpendicular to the thickness direction of the least one of the well layers.

According to an embodiment, in a method of producing a semiconductor light-emitting element including a nitride-based Group III-V compound semiconductor and having a structure in which an active layer including one or a plurality of well layers is sandwiched between a p-side cladding layer and an n-side cladding layer, the method includes a step of modulating the composition of at least one of the well layers in the direction perpendicular to the thickness direction of the at least one of the well layers during the growth of the active layer.

In an embodiment, the composition of at least one of the well layers is modulated such that the band gap energy of the at least one of the well layers increases or decreases in the direction from the n-side cladding layer to the p-side cladding layer in accordance with the case where the luminous efficiency of the semiconductor light-emitting element is increased or decreased. In general, the composition of the at least one of the well layers is modulated by modulating a growth condition (such as the growth temperature, the vapor pressure of the growth material, or the flow rate of a carrier gas used for transporting the growth material) during the growth of the at least one of the well layers. Typically, the composition of the at least one of the well layers is modulated by modulating the growth temperature during the growth of the at least one of the well layer well layers.

The active layer typically has a multiquantum well structure, but may have a single quantum well structure.

The n-side cladding layer typically is an n-type layer. Alternatively, the n-side cladding layer may be a composite layer including an n-type layer and an undoped layer. Similarly, the p-side cladding layer typically is a p-type layer, but may be a composite layer including a p-type layer and an undoped layer.

The maximum growth temperature T (° C.) after the growth of the active layer is controlled so as to satisfy the relationship T<1,350−0.75λ, preferably T<1,250−0.75λ, wherein λ represents the emission wavelength (nm) of the semiconductor light-emitting element, thereby preventing degradation of the active layer due to the growth temperature of a layer grown after the growth of the active layer.

The emission wavelength of the semiconductor light-emitting element is generally selected to be in the range of 370 to 650 nm corresponding to the emission wavelength ranging from the ultraviolet to the infrared. For example, the emission wavelength is selected to be in the range of 430 to 550 nm corresponding to the emission wavelength ranging from blue to green, in the range of 430 to 480 nm corresponding to the blue-light emission wavelength, or in the range of 500 to 550 nm corresponding to the green-light emission wavelength.

The drive current density of the semiconductor light-emitting element is selected according to need. For example, the drive current density is 10 A/cm² or more, 50 A/cm² or more, or 100 A/cm² or more. During the driving of the semiconductor light-emitting element, modulation of a part of or all of the intensity of light emission may be performed by a driving current amplitude modulation, by combining a current pulse width modulation with a current amplitude modulation, or by combining a current density modulation with a current amplitude modulation.

The nitride-based Group III-V compound semiconductor constituting the semiconductor light-emitting element contains at least one element selected from Al, B, Ga, In, and Tl as a Group III element. The nitride-based Group III-V compound semiconductor is generally represented by AlₓB_{y}Ga_{1-x-y-z}In_{z}AsᵤN₁₋ᵤ₋ᵥPᵥ (wherein 0≦x≦1, 0≦y≦1, 0≦z≦1, 0≦u≦1, 0≦v≦1, 0≦x+y+z<1, and 0≦u+v<1), more specifically represented by AlₓB_{y}Ga_{1-x-y-z}In_{z}N (wherein 0≦x≦1, 0≦y≦1, 0≦z≦1, and 0≦x+y+z<1), and typically represented by AlₓGa_{1-x-z}In_{z}N (wherein 0≦x≦1 and 0≦z≦1). Specific examples of the nitride-based Group III-V compound semiconductor include GaN, InN, AlN, AlGaN, InGaN, and AlGaInN. The well layer is typically composed of a nitride-based Group III-V compound semiconductor containing indium (In). More typically, the well layer is composed of a nitride-based Group III-V compound semiconductor containing indium (In) and gallium (Ga). More specifically, such a nitride-based Group III-V compound semiconductor containing In and Ga is represented by AlₓB_{y}Ga_{1-x-y-z}In_{z}AsᵤN₁₋ᵤ₋ᵥPᵥ (wherein 0≦x≦1, 0≦y≦1, 0<z≦1, 0≦u≦1, 0≦v≦1, 0≦x+y+z<1, and 0≦u+v<1), more specifically represented by AlₓB_{y}Ga_{1-x-y-z}In_{z}N (wherein 0≦x≦1, 0≦y≦1, 0<z≦1, and 0≦x+y+z<1), and typically represented by AlₓGa_{1-x-z}In_{z}N (wherein 0≦x≦1 and 0<z≦1). Specific examples thereof include InGaN and AlGaInN but are not limited thereto.

The nitride-based Group III-V compound semiconductor can be typically grown by an epitaxial growth method such as a metalorganic chemical vapor deposition (MOCVD) method, a hydride vapor phase epitaxial growth, a halide vapor phase epitaxial growth, or a molecular beam epitaxy (MBE) method. However, the method is not limited thereto. Various types of substrates can be used for growing the nitride-based Group III-V compound semiconductor thereon. Specific examples thereof include substrates made of sapphire (a sapphire substrate including a C-plane, an A-plane, an R-plane, or the like, or a sapphire substrate including a plane different from these planes), SiC (a SiC substrate including 6H—SiC, 4H—SiC, or 3C—SiC), Si, ZnS, ZnO, LiMgO, GaAs, spinel (MgAl₂O₄, ScAlMgO₄), garnet, or a nitride-based Group III-V compound semiconductor (such as GaN).

In general, a nitride-based Group III-V compound semiconductor is grown in the C-plane orientation on a substrate. In particular, the nitride-based Group III-V compound semiconductor is preferably grown in a Ga plane (also referred to as C+plane) growth. Furthermore, a principal surface of the active layer is preferably tilted in the range of 0.25° to 2°, more preferably in the range of 0.3° to 1° with respect to the C-plane.

Examples of the semiconductor light-emitting element include a light-emitting diode and a laser diode.

When the semiconductor light-emitting element is a light-emitting diode, in order that light emitted from the active layer is reflected at a light-extracting surface to improve the light extraction efficiency, a reflective layer is preferably provided in the light-emitting diode. The distance between the reflective layer and the active layer is selected to be more than 0.5×λ/n and less than λ/n wherein the refractive index of the nitride-based Group III-V compound semiconductor constituting the semiconductor light-emitting element is represented by n and the emission wavelength of the nitride-based Group III-V compound semiconductor is represented by λ (nm). An electrode (e.g., p-side electrode) of the light-emitting diode can be used as the reflective layer, but the reflective layer is not limited thereto.

When the active layer has a multiquantum well structure in which well layers and barrier layers are alternately laminated, the density of the well layers in the active layer having the multiquantum well structure may be uniform in the thickness direction of the well layers. However, from the standpoint that a significant shift in the emission wavelength caused by an increase in the drive current density of the semiconductor light-emitting element is suppressed, and the luminance can be controlled over a wider range, the well layers in the active layer are arranged such that the relationship d₁<d₂ is satisfied wherein the well layer density of a well layer of the active layer located adjacent to the n-side cladding layer is represented by d₁ and the well layer density of a well layer of the active layer located adjacent to the p-side cladding layer is represented by d₂. In order to vary the density of the well layers included in the active layer, for example, preferably, the thicknesses of the well layers are uniform, and the thicknesses of the barrier layers are varied (more specifically, the thickness of a barrier layer located adjacent to the p-side cladding layer in the active layer is controlled so as to be smaller than that of a barrier layer located adjacent to the n-side cladding layer), but the method is not limited thereto. Alternatively, the thicknesses of the barrier layers may be uniform, and the thicknesses of the well layers may be varied (more specifically, the thickness of a well layer located adjacent to the p-side cladding layer in the active layer is controlled so as to be larger than that of a well layer located adjacent to the n-side cladding layer). Alternatively, both the thicknesses of the well layers and the thicknesses of the barrier layers may be varied.

Herein, the well layer density d₁ and the well layer density d₂ are defined as follows. Specifically, when an active layer having a total thickness of t₀ is divided into two portions, the thickness of a first area, which is an area of the active layer adjacent to the n-side cladding layer, is represented by t₁ and the thickness of a second area, which is an area of the active layer adjacent to the p-side cladding layer, is represented by t₂ wherein t₀=t₁+t₂. In addition, the number of well layers included in the first area is represented by WL₁ (which is a positive number but is not limited to an integer). The number of well layers included in the second area is represented by WL₂ (which is a positive number but is not limited to an integer). The total number of well layers WL is represented by WL=WL₁+WL₂. When a single well layer (having a thickness of t_{IF}) is disposed over the first area and the second area, the number of well layers included only in the first area is represented by WL′₁, the number of well layers included only in the second area is represented by WL′₂, the thickness of a part of the well layer disposed over the first area and the second area, the part being included in the first area, is represented by t_{IF-1}, and the thickness of the remaining part of the well layer that is included in the second area is represented by t_{IF-2} (wherein t_{IF}=t_{IF-1}+t_{IF-2}). In this case, the following relationships are satisfied.

WL₁=WL′₁+ΔWL₁

WL₂=WL′₂+ΔWL₂

In the above formulae, the relationship ΔWL₁+ΔWL₂=1 is satisfied.

In addition, the following relationships are satisfied.

$$\begin{matrix}WL = {WL}_{1} + {WL}_{2} \\ = {WL}_{1}^{′} + {WL}_{2}^{′} + 1 \end{matrix}$$

$$\begin{matrix}Δ {WL}_{1} = {t}_{IF \text{-} 1} / {t}_{IF} \\ Δ {WL}_{2} = {t}_{IF \text{-} 2} / {t}_{IF}\end{matrix}$$

The well layer density d₁ and the well layer density d₂ can be calculated using the following formulae (1) and (2), wherein k≡(t₀/WL).

$$\begin{matrix}{d}_{1} = ( {WL}_{1} / WL ) / ( {t}_{1} / {t}_{0} ) \\ = k ( {WL}_{1} / {t}_{1} ) ( 1 ) \\ {d}_{2} = ( {WL}_{2} / WL ) / ( {t}_{2} / {t}_{0} ) \\ = k ( {WL}_{2} / {t}_{2} ) ( 2 )\end{matrix}$$

Here, the well layers in the active layer can be arranged so as to satisfy the relationship d₁<d₂ when the well layer density in the first area ranging from the boundary between the active layer and the n-side cladding layer to a position corresponding to the thickness (2 t₀/3) is represented by d₁, and the well layer density in the second area ranging from the boundary between the active layer and the p-side cladding layer to a position corresponding to the thickness (t₀/3) is represented by d₂. Alternatively, the well layers in the active layer can be arranged so as to satisfy the relationship d₁<d₂ when the well layer density in the first area ranging from the boundary between the active layer and the n-side cladding layer to a position corresponding to the thickness (t₀/2) is represented by d₁, and the well layer density in the second area ranging from the boundary between the active layer and the p-side cladding layer to a position corresponding to the thickness (t₀/2) is represented by d₂. Alternatively, the well layers in the active layer can be arranged so as to satisfy the relationship d₁<d₂ when the well layer density in the first area ranging from the boundary between the active layer and the n-side cladding layer to a position corresponding to the thickness (t₀/3) is represented by d₁, and the well layer density in the second area ranging from the boundary between the active layer and the p-side cladding layer to a position corresponding to the thickness (2t₀/3) is represented by d₂. Herein, the well layers in the active layer are preferably arranged so as to satisfy 1<d₂/d₁≦20, preferably 1.2≦d₂/d₁≦10, and more preferably 1.5≦d₂/d₁≦5. The number of well layers (WL) in the active layer is 2 or more, and preferably 4 or more.

In a semiconductor light-emitting element having the above-described active layer, when the emission wavelength of the active layer at a drive current density of 30 A/cm² is represented by λ₂ (nm), and the emission wavelength of the active layer at a drive current density of 300 A/cm² is represented by λ₃ (nm), the following relationships are preferably satisfied:

500 (nm)≦λ₂≦550 (nm)

0≦|λ₂−λ₃|≦5 (nm)

Alternatively, when the emission wavelength of the active layer at a drive current density of 1 A/cm² is represented by λ₁ (nm), the emission wavelength of the active layer at a drive current density of 30 A/cm² is represented by λ₂ (nm), and the emission wavelength of the active layer at a drive current density of 300 A/cm² is represented by λ₃ (nm), the following relationships are preferably satisfied:

500 (nm)≦λ₂≦550 (nm)

0≦|λ₁−λ₂|≦10 (nm)

0≦|λ₂−λ₃|≦5 (nm)

Note that the drive current density of the semiconductor light-emitting element is calculated by dividing the drive current by the area of the active layer (area of the joined portion).

Alternatively, in a semiconductor light-emitting element having the above-described active layer, when the emission wavelength of the active layer at a drive current density of 30 A/cm² is represented by λ₂ (nm), and the emission wavelength of the active layer at a drive current density of 300 A/cm² is represented by λ₃ (nm), the following relationships are preferably satisfied:

430 (nm)≦λ₂≦480 (nm)

0≦|λ₂−λ₃|≦2 (nm)

Alternatively, when the emission wavelength of the active layer at a drive current density of 1 A/cm² is represented by λ₁ (nm), the emission wavelength of the active layer at a drive current density of 30 A/cm² is represented by λ₂ (nm), and the emission wavelength of the active layer at a drive current density of 300 A/cm² is represented by λ₃ (nm), the following relationships are preferably satisfied:

430 (nm)≦λ₂≦480 (nm)

0≦|λ₁−λ₂≦5 (nm)

0≦|λ₂−λ₃|≦2 (nm)

This semiconductor light-emitting element can be used for various types of units and devices (such as a backlight, a display unit, an illumination device, and an electronic device).

According to an embodiment, in a backlight in which a plurality of semiconductor red-light-emitting elements, a plurality of semiconductor green-light-emitting elements, and a plurality of semiconductor blue-light-emitting elements are arranged, at least one of the semiconductor red-light-emitting elements, the semiconductor green-light-emitting elements, and the semiconductor blue-light-emitting elements includes a nitride-based Group III-V compound semiconductor and has a structure in which an active layer including one or a plurality of well layers is sandwiched between a p-side cladding layer and an n-side cladding layer, and the composition of at least one of the well layers of the active layer is modulated in the direction perpendicular to the thickness direction of the at least one of the well layers.

This backlight is typically a light-emitting diode backlight. More specifically, in such a light-emitting diode backlight, semiconductor light-emitting elements are formed as light-emitting diodes and, for example, a plurality of red-light-emitting diodes, green-light-emitting diodes, and blue-light-emitting diodes are arranged. A red-light-emitting diode, a green-light-emitting diode, and a blue-light-emitting diode constitute one unit (one pixel). For example, a light-emitting diode including an AlGaInP-based semiconductor can be used as the red-light-emitting diode, and a light-emitting diode including a nitride-based Group III-V compound semiconductor can be used as the green-light-emitting diode and the blue-light-emitting diode. However, the light-emitting diodes are not limited thereto.

According to an embodiment, in a display unit in which a plurality of semiconductor red-light-emitting elements, a plurality of semiconductor green-light-emitting elements, and a plurality of semiconductor blue-light-emitting elements are arranged, at least one of the semiconductor red-light-emitting elements, the semiconductor green-light-emitting elements, and the semiconductor blue-light-emitting elements includes a nitride-based Group III-V compound semiconductor and has a structure in which an active layer including one or a plurality of well layers is sandwiched between a p-side cladding layer and an n-side cladding layer, and the composition of at least one of the well layers of the active layer is modulated in the direction perpendicular to the thickness direction of the at least one of the well layers.

Examples of the display unit include various types of units. Specific examples of the display unit include a light-emitting diode display in which the above-described semiconductor light-emitting elements are formed as light-emitting diodes, and a plurality of pixels including the light-emitting diodes are arranged in a matrix shape (an active-matrix light-emitting diode display or a passive-matrix light-emitting diode display); a transmissive or semi-transmissive liquid crystal display including a liquid crystal panel and a backlight (light-emitting diode backlight) having at least one light-emitting diode described above; and a projection display including a light valve element and a light source (light-emitting diode light source) having at least one light-emitting diode described above. Examples of the light valve element that can be used include a transmissive or reflective liquid crystal display panel, and micro-electro-mechanical systems (MEMS) such as a digital micro-mirror device (DMD).

According to an embodiment, in an electronic device including one or a plurality of semiconductor light-emitting elements, at least one of the semiconductor light-emitting elements includes a nitride-based Group III-V compound semiconductor and has a structure in which an active layer including one or a plurality of well layers is sandwiched between a p-side cladding layer and an n-side cladding layer, and the composition of at least one of the well layers of the active layer is modulated in the direction perpendicular to the thickness direction of the at least one of the well layers.

This electronic device is not particularly limited as long as the electronic device includes at least one semiconductor light-emitting element used for the purpose of a backlight of a liquid crystal display, a display, an illumination, or the like. Examples of the electronic device include both portable electronic devices and non-portable electronic devices. Specific examples thereof include not only the above-mentioned various display units but also cell phones, mobile devices, robots, personal computers, automobile-installed equipment, and various household electrical appliances.

According to an embodiment, in a light-emitting unit including one or a plurality of semiconductor light-emitting elements and at least one color conversion material on which light emitted from the one or the plurality of the semiconductor light-emitting elements is incident, at least one of the semiconductor light-emitting elements includes a nitride-based Group III-V compound semiconductor and has a structure in which an active layer including one or a plurality of well layers is sandwiched between a p-side cladding layer and an n-side cladding layer, and the composition of at least one of the well layers of the active layer is modulated in the direction perpendicular to the thickness direction of the at least one of the well layers.

In this light-emitting unit, a color conversion can be performed by allowing light emitted from a semiconductor light-emitting element to enter a color-conversion material. For example, when a semiconductor light-emitting element that emits blue light and at least one color-conversion material selected from a green color-conversion material, a yellow color-conversion material, and a red color-conversion material, the color-conversion material is excited by light that has an emission wavelength of blue light and that is emitted from the semiconductor blue-light-emitting element, thereby allowing light having a color of at least one of green, yellow, and red to be emitted. For example, phosphor-containing materials are used as the color-conversion materials.

Except for the above-described features, the same features as those described in the previous two embodiments can apply to the last three embodiments.

In the above-described six embodiments, the composition of at least one well layer in an active layer of a semiconductor light-emitting element is modulated in the direction perpendicular to the thickness direction of the well layer. Accordingly, the relative positions of the wave function distribution of electrons and the wave function distribution of holes in the well layer can be controlled during the operation of the semiconductor light-emitting element, and thus the luminous efficiency of the semiconductor light-emitting element can be controlled.

According an embodiment, the luminous efficiency can be easily controlled by modulating the composition of a well layer in an active layer. In particular, a semiconductor light-emitting element in which a decrease in the luminous efficiency can be easily prevented even when the emission wavelength is increased, and a method of producing a semiconductor light-emitting element by which such a semiconductor light-emitting element can be easily produced can be provided. In addition, a high-performance backlight, display, electronic device, and the like can be realized using the semiconductor light-emitting element.

Additional features and advantages are described herein, and will be apparent from the following Detailed Description and the figures.

### BRIEF DESCRIPTION OF THE FIGURES

FIG. 1 is a cross-sectional view showing a GaN-based light-emitting diode used in experiments performed by the present inventors;

FIG. 2 is a cross-sectional view showing the detailed structure of an active layer of the GaN-based light-emitting diode shown in FIG. 1;

FIG. 3 is a cross-sectional view showing a GaN-based light-emitting diode used in an electroluminescence measurement performed by the present inventors;

FIG. 4 is a graph showing the results of the electroluminescence measurement performed by the present inventors;

FIGS. 5A to 5C are schematic diagrams illustrating the principle;

FIGS. 6A and 6B are schematic diagrams illustrating the principle;

FIGS. 7A and 7B are schematic diagrams illustrating the principle;

FIG. 8 is a cross-sectional view showing a GaN-based light-emitting diode according to a first embodiment;

FIG. 9 is a cross-sectional view showing the detailed structure of an active layer of the GaN-based light-emitting diode shown in FIG. 8;

FIGS. 10A and 10B are graphs illustrating a method of producing a GaN-based light-emitting diode according to a first embodiment;

FIG. 11 is a graph showing the results of an electroluminescence measurement using GaN-based light-emitting diodes according to a first embodiment;

FIG. 12 is a graph illustrating GaN-based light-emitting diodes according to a second embodiment;

FIG. 13 is a graph showing the relationship between the drive current density and the optical output of GaN-based light-emitting diodes according to a second embodiment;

FIG. 14 is a graph showing the relationship between the drive current density and the emission peak wavelength of the GaN-based light-emitting diodes according to a second embodiment;

FIG. 15 is a graph showing the relationship between the drive current density and the emission peak wavelength of GaN-based light-emitting diodes according to a second embodiment;

FIG. 16 is a schematic diagram showing a transmissive liquid crystal display according to a third embodiment;

FIG. 17 is a schematic view showing a projection display according to a fourth embodiment;

FIG. 18 is a schematic view showing a projection display according to a fifth embodiment;

FIG. 19 is a schematic diagram showing a passive-matrix light-emitting diode display according to a sixth embodiment; and

FIG. 20 is a schematic diagram showing an active-matrix light-emitting diode display according to a seventh embodiment.

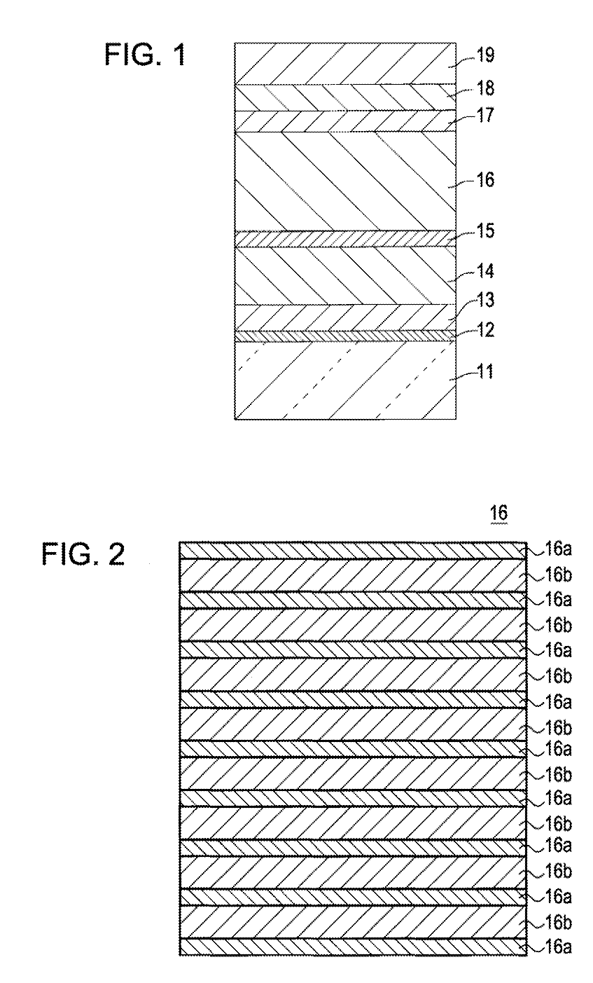

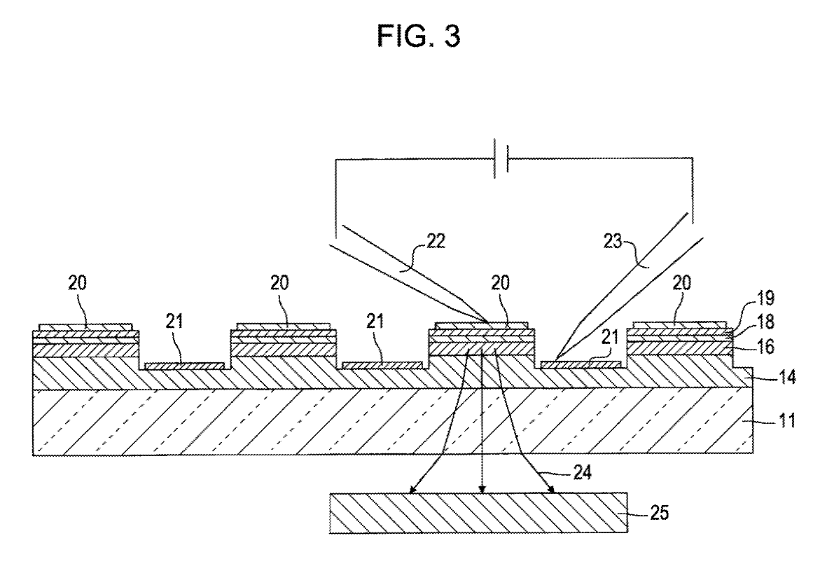

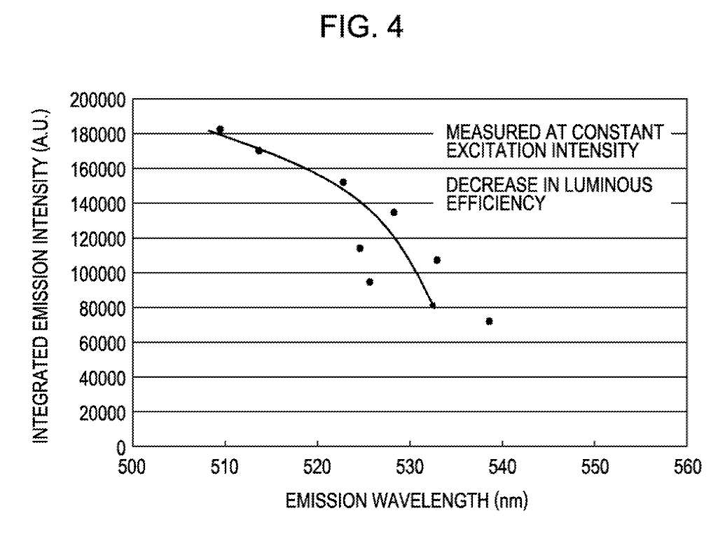

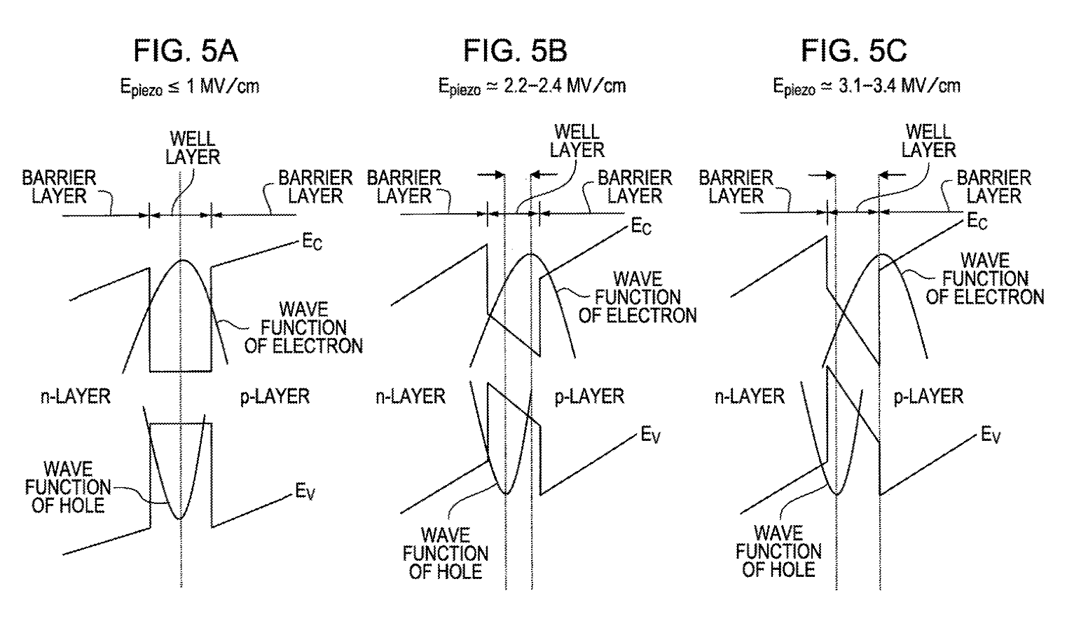

### DETAILED DESCRIPTION

The present application will now be described with reference to the drawings according to an embodiment.

First, a GaN-based light-emitting diode according to a first embodiment will be described.

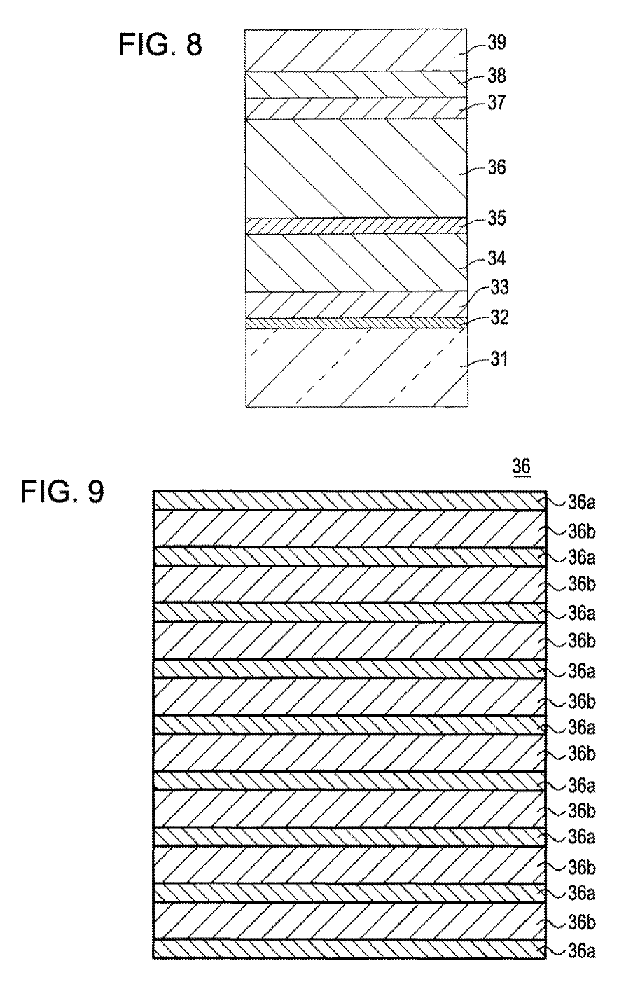

FIG. 8 is a cross-sectional view of the GaN-based light-emitting diode, and FIG. 9 is a cross-sectional view showing the detailed structure of an active layer of the GaN-based light-emitting diode shown in FIG. 8.

As shown in FIG. 8, in the GaN-based light-emitting diode, a low-temperature GaN buffer layer 32, an undoped GaN layer 33, an n-type GaN layer 34 doped with, for example, Si, an undoped GaN layer 35, an active layer 36 having an InGaN/GaN multiquantum well structure, an undoped GaN layer 37, a p-type AlGaN layer 38 doped with, for example, Mg, and a p-type GaN layer 39 doped with, for example, Mg are sequentially stacked on a sapphire substrate 31 having a principal surface of, for example, a C-plane. The n-type GaN layer 34 mainly constitutes an n-side cladding layer, and the p-type AlGaN layer 38 mainly constitutes a p-side cladding layer.

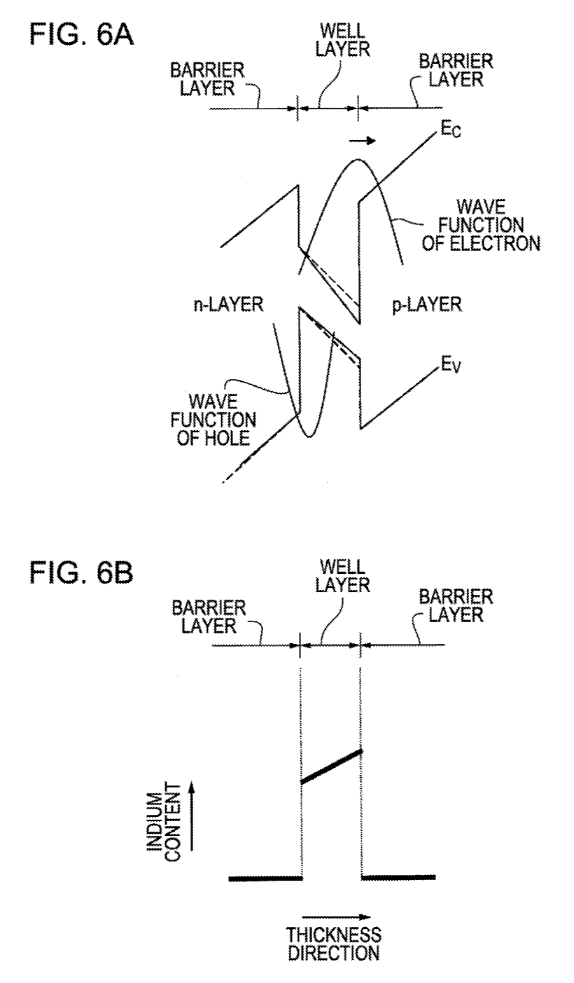

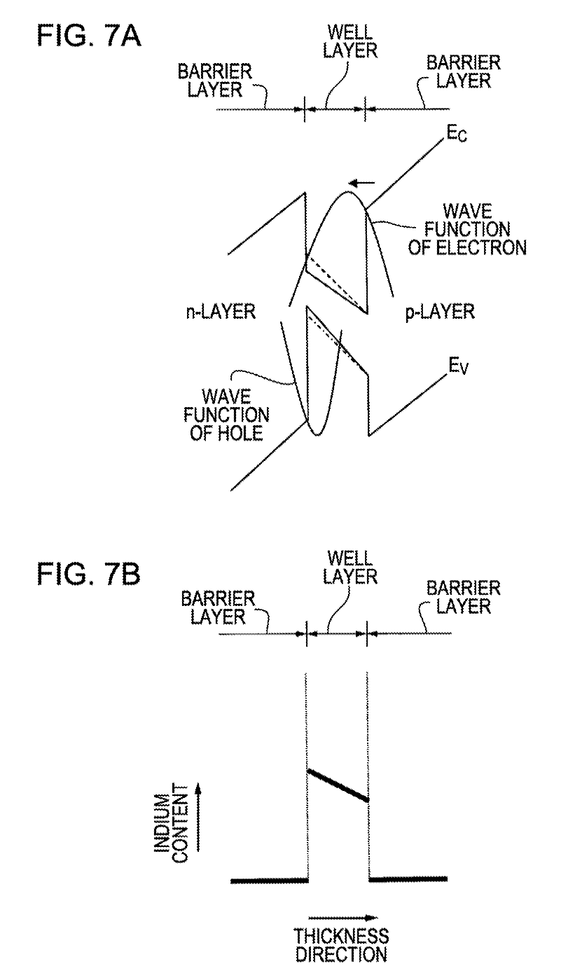

As shown in FIG. 9, the active layer 36 is prepared by alternately stacking well layers composed of InGaN sublayers 36a and barrier layers composed of GaN sublayers 36b. This active layer 36 is characterized in that the indium (In) content of each of the well layers composed of the InGaN sublayers 36a is gradually decreased in the direction from the n-type GaN layer 34 to the p-type AlGaN layer 38, as shown in FIG. 7B, or the In content thereof is gradually increased in the direction from the n-type GaN layer 34 to the p-type AlGaN layer 38, as shown in FIG. 6B. Accordingly, the band gap energy of the well layer composed of the InGaN sublayer 36a is gradually increased in the direction from the n-type GaN layer 34 to the p-type AlGaN layer 38, as shown in FIG. 7A, or the band gap energy thereof is gradually decreased in the direction from the n-type GaN layer 34 to the p-type AlGaN layer 38, as shown in FIG. 6A. The variation width of the In content in the InGaN sublayer 36a is preferably 1% or more, and more preferably 2% or more. Alternatively, the variation width of the band gap E_{g} of the InGaN sublayer 36a is preferably 20 meV or more, and more preferably 40 meV or more.

Specific examples of the thickness and the like of each layer constituting the GaN-based light-emitting diode will be described. The low-temperature GaN buffer layer 32 has a thickness of 30 nm, the undoped GaN layer 33 has a thickness of 1 μm, the n-type GaN layer 34 has a thickness of 3 μm and a Si doping concentration of 5×10¹⁸/cm³, and the undoped GaN layer 35 has a thickness of 5 nm. The active layer 36 includes the InGaN sublayers 36a functioning as well layers each having a thickness of 3 nm and the GaN sublayers 36b functioning as barrier layers each having a thickness of 15 nm that are alternately stacked. The active layer 36 has a multiquantum well structure including nine wells in which nine well layers are separated by eight barrier layers (see FIG. 9). The average In content of each of the InGaN sublayers 36a functioning as well layers is determined in accordance with the emission wavelength. For example, an average In content of 0.23 corresponds to an emission wavelength of 515 nm. The undoped GaN layer 37 has a thickness of 10 nm, the p-type AlGaN layer 38 has a thickness of 20 nm, a Mg doping concentration of 5×10¹⁹/cm³, and an aluminum content of 0.15, and the p-type GaN layer 39 has a thickness of 100 nm and a Mg doping concentration of 5×10¹⁹/cm³.

Although a description and an illustration are omitted, in this GaN-based light-emitting diode, for example, the upper portion of the n-type GaN layer 34, the undoped GaN layer 35, the active layer 36, the undoped GaN layer 37, the p-type AlGaN layer 38, and the p-type GaN layer 39 are patterned in a predetermined mesa shape. A p-side electrode is formed on the p-type GaN layer 39, and an n-side electrode is formed on the n-type GaN layer 34 adjacent to the mesa portions. The p-side electrode is made of, for example, Ag/Ni, and the n-side electrode is made of, for example, Ti/Al. However, the materials of these electrodes are not limited thereto.

Next, a method of producing the GaN-based light-emitting diode will be described.

As shown in FIG. 8, a sapphire substrate 31 having a C-plane as a principal surface is cleaned in hydrogen carrier gas at 1,050° C. for 10 minutes. The temperature is then decreased to 500° C., and ammonia, which is a nitrogen source, is supplied. In addition, trimethylgallium (TMG), which is a gallium source, is supplied by switching valves, and a low-temperature GaN buffer layer 32 is grown by, for example, an MOCVD method. The temperature is increased to 1,020° C. in a state in which the supply of TMG is temporarily stopped, and the supply of TMG is then started again, thus growing the undoped GaN layer 33. Subsequently, supply of SiH₄ is started, thus growing a Si-doped n-type GaN layer 34. Next, the supply of SiH₄ is stopped, and ammonia and TMG are supplied to grow an undoped GaN layer 35. Next, the supply of TMG and SiH₄ is stopped, the carrier gas is switched from hydrogen to nitrogen, and the temperature is decreased to 750° C.

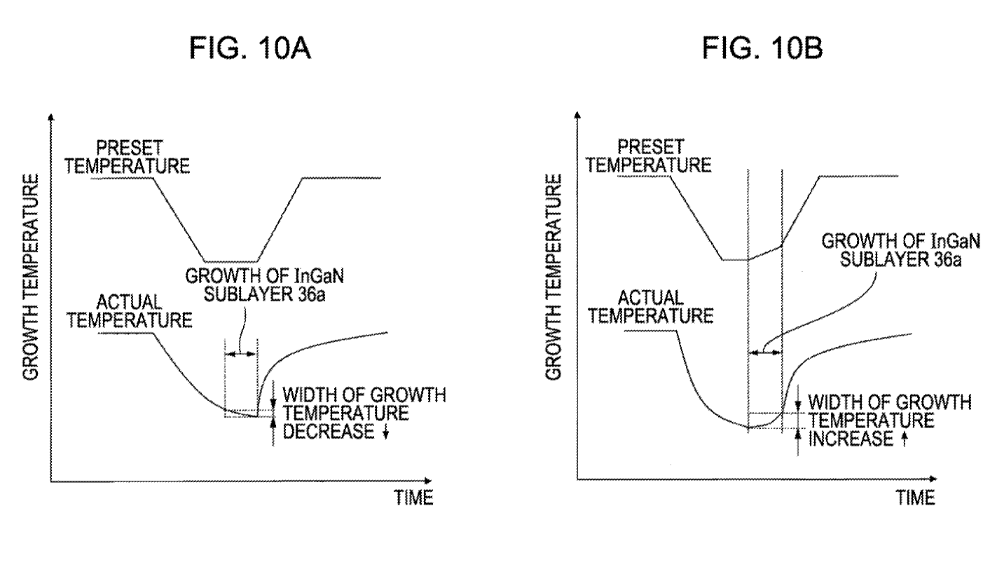

Subsequently, trimethylindium (TMI) is then supplied as an indium source by switching valves while triethylgallium (TEG) is supplied as a gallium source. Thus, as shown in FIG. 9, well layers each composed of an InGaN sublayer 36a and barrier layers each composed of a GaN sublayer 36b are alternately grown to form an active layer 36 having an InGaN/GaN multiquantum well structure. During the growth of this active layer 36, by selecting growth conditions of the well layers composed of the InGaN sublayers 36a, each of the InGaN sublayers 36a is formed such that the In content of the InGaN sublayer 36a is gradually decreased or gradually increased in the direction from the n-type GaN layer 34 to the p-type AlGaN layer 38. For this purpose, for example, the amount of In incorporated is decreased by gradually increasing the growth temperature of the InGaN sublayer 36a, by decreasing the vapor pressure of the In source, by decreasing the flow rate of the carrier gas used for transporting the In source, or by using these methods in combination. Alternatively, the amount of In incorporated is increased by gradually decreasing the growth temperature of the InGaN sublayer 36a, by increasing the vapor pressure of the In source, by increasing the flow rate of the carrier gas used for transporting the In source, or by using these methods in combination. FIGS. 10A and 10B show examples in which the growth temperature of the InGaN sublayer 36a is changed. FIG. 10A shows the case where the In content of the InGaN sublayer 36a is gradually increased in the direction from the n-type GaN layer 34 to the p-type AlGaN layer 38 (Type A). FIG. 10B shows the case where the In content of the InGaN sublayer 36a is gradually decreased in the direction from the n-type GaN layer 34 to the p-type AlGaN layer 38 (Type B). Each of FIGS. 10A and 10B shows the preset temperature in a growth temperature sequence and the actual temperature of a substrate surface (the temperature that is actually measured). In FIG. 10A, the width of the growth temperature decrease is, for example, about 3° C. In FIG. 10B, the width of growth temperature increase is preferably 5° C. or higher, more preferably 7° C. or higher, and further preferably 10° C. or higher, but is not limited thereto. This width of growth temperature increase is preferably applied to the case where the active layer 36 is grown at a growth temperature in the range of 600° C. to 850° C., more preferably in the range of 650° C. to 800° C.

Next, the temperature is increased to 800° C. while an undoped GaN layer 37 is grown on the active layer 36. Supply of trimethylaluminum (TMA), which is an aluminum source, and biscyclopentadienyl magnesium (Cp₂Mg), which is a magnesium source, is started, thus growing a Mg-doped p-type AlGaN layer 38 having a thickness of 20 nm. Subsequently, the supply of TEG, TMA, and Cp₂Mg is stopped, the carrier gas is switched from nitrogen to hydrogen, and the temperature is increased to 850° C. The supply of TMG and Cp₂Mg is started, thus growing a Mg-doped p-type GaN layer 39. The supply of TMG and Cp₂Mg is then stopped, the temperature is decreased, and the supply of ammonia is stopped at 600° C. The temperature is decreased to room temperature to finish the growth of the crystals. In this case, the maximum growth temperature T (° C.) after the growth of the active layer 36 is 850° C., which is the growth temperature of the p-type GaN layer 39. When the emission wavelength λ is less than 666 nm, the relationship T<1,350−0.75λ is satisfied. Accordingly, degradation of the active layer 36 can be prevented.

The sapphire substrate 31 obtained after the crystal growth as described above is annealed in a nitrogen atmosphere at 800° C. for 10 minutes to activate Mg doped in the p-type AlGaN layer 38 and the p-type GaN layer 39.

Subsequently, as in the production process of a normal light-emitting diode ranging from a wafer process to a chip-forming process, more specifically, photolithography, etching, metal evaporation, and the like are performed, the resulting substrate is separated into chips by dicing, and resin molding and packaging are then performed. Consequently, various types of GaN-based light-emitting diodes, such as a shell-type light-emitting diode and a surface-mounted light-emitting diode, can be produced.

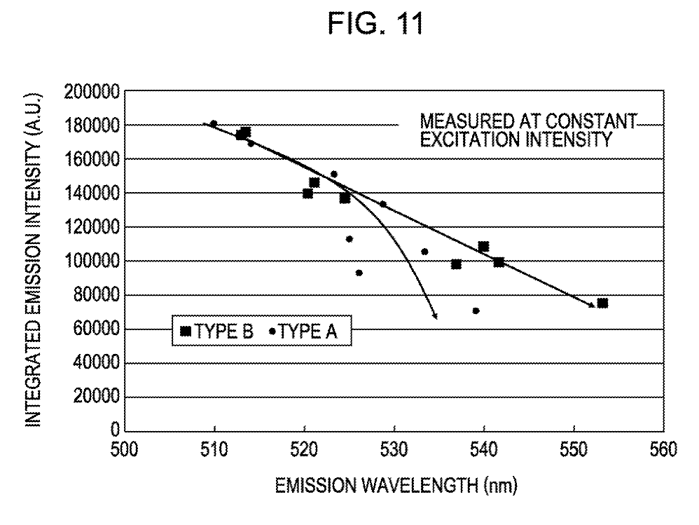

FIG. 11 is a graph showing the relationship between the emission wavelength and the emission intensity when the GaN-based light-emitting diode of Type A and the GaN-based light-emitting diode of Type B are excited under the same excitation condition. In FIG. 11, the horizontal axis represents the emission wavelength, and the vertical axis represents the emission intensity with arbitrary units. Comparing Type A with Type B, it was confirmed that the emission intensity in Type B became higher than that in Type A in the range extending from an emission wavelength of about 525 nm. More specifically, the emission intensity in Type B was higher than that in Type A by about 10% at an emission wavelength of 530 nm, and by about 50% at an emission wavelength of 540 nm. Accordingly, the emission intensity in Type B is higher than that in Type A particularly in the range extending from an emission wavelength of about 530 nm, and thus a GaN-based light-emitting diode with a low electric power consumption and a high output can be realized.

As described above, according to a first embodiment, the In content of each of the well layers composed of the InGaN sublayer 36a of the active layer 36 is gradually decreased or gradually increased in the direction from the n-type GaN layer 34 to the p-type AlGaN layer 38, as shown in FIG. 7B or 6B. In addition, the band gap energy of each of the well layers composed of the InGaN sublayer 36a is gradually increased or gradually decreased in the direction from the n-type GaN layer 34 to the p-type AlGaN layer 38, as shown in FIG. 7A or 6A. Consequently, the wave function distribution of electrons can be made close to or far from the wave function distribution of holes in each of the well layers composed of the InGaN sublayer 36a. In the former case, the luminous efficiency of the GaN-based light-emitting diode can be increased, and in the latter case, the luminous efficiency can be decreased. In particular, in the former case, a problem of a decrease in the luminous efficiency when the emission wavelength of a GaN-based light-emitting diode in the related art is increased can be solved. Furthermore, a GaN-based light-emitting diode having an emission wavelength in the range from yellow to red, which is believed to be very difficult to realize using a GaN-based light-emitting diode because of a decrease in the luminous efficiency, can be realized. In addition, by applying the above GaN-based light-emitting diode with a high luminous efficiency to a display or the like, the electric power consumption can be reduced, and in addition, the pulse width for pulse-driving the GaN-based light-emitting diode can also be decreased compared with the case where a GaN-based light-emitting diode in the related art is driven at the same luminance, thus increasing the lifetime of the GaN-based light-emitting diode. On the other hand, in the latter case, for example, the luminous efficiency of two or more types of GaN-based light-emitting diodes having different emission wavelengths can be made the same.

A second embodiment will now be described.

In the second embodiment, the structure of the active layer 36 is different from that of the first embodiment. More specifically, well layers in the active layer 36 are arranged such that when the density of well layers disposed adjacent to the n-type GaN layer 34 in the active layer 36 is represented by d₁ and the density of well layers disposed adjacent to the p-type AlGaN layer 38 is represented by d₂, the relationship d₁<d₂ is satisfied. In order to vary the densities of the well layers in the active layer 36, for example, preferably, the thicknesses of the well layers are made the same, and the thicknesses of barrier layers are varied (more specifically, the thickness of barrier layers disposed adjacent to the p-type AlGaN layer 38 in the active layer 36 is made smaller than that of barrier layers disposed adjacent to the n-type GaN layer 34), but the method is not limited thereto. Alternatively, the thicknesses of the barrier layers may be made the same, and the thicknesses of the well layers may be varied (more specifically, the thickness of well layers disposed adjacent to the p-type AlGaN layer 38 in the active layer 36 is made larger than that of well layers disposed adjacent to the n-type GaN layer 34). Alternatively, both the thicknesses of the well layers and the thicknesses of the barrier layers may be varied. The well layers in the active layer 36 are arranged such that the relationship 1<d₂/d₁≦20, preferably 1.2≦d₂/d₁≦10, and more preferably 1.5≦d₂/d₁≦5 is satisfied.

A green-light-emitting GaN-based light-emitting diode having a multiquantum well structure including an active layer 36 having nine well layers and eight barrier layers was prepared. An experiment was performed in which the emission ratio from each well layer of the active layer 36 was visually determined when light was emitted from the GaN-based light-emitting diode. In this GaN-based light-emitting diode, the thickness of the n-type GaN layer 34 was 3 μm. Instead of forming the p-type AlGaN layer 38 and the p-type GaN layer 39, a p-type GaN layer having a thickness of 120 nm was formed. The thickness of each of the undoped GaN layers 33 and 37 was 5 nm. The compositions of InGaN sublayers 36a functioning as well layers in the active layer 36 were modulated as in the first embodiment, but in this embodiment, the In content was set to 0.23. Each of the InGaN sublayer 36a had a thickness of 3 nm, and each of GaN sublayer 36b functioning as barrier layers had a thickness of 15 nm. In this GaN-based light-emitting diode (Sample 1), the emission peak wavelength was 515 nm and the luminous efficiency was 180 mW/A at a drive current density of 60 A/cm².

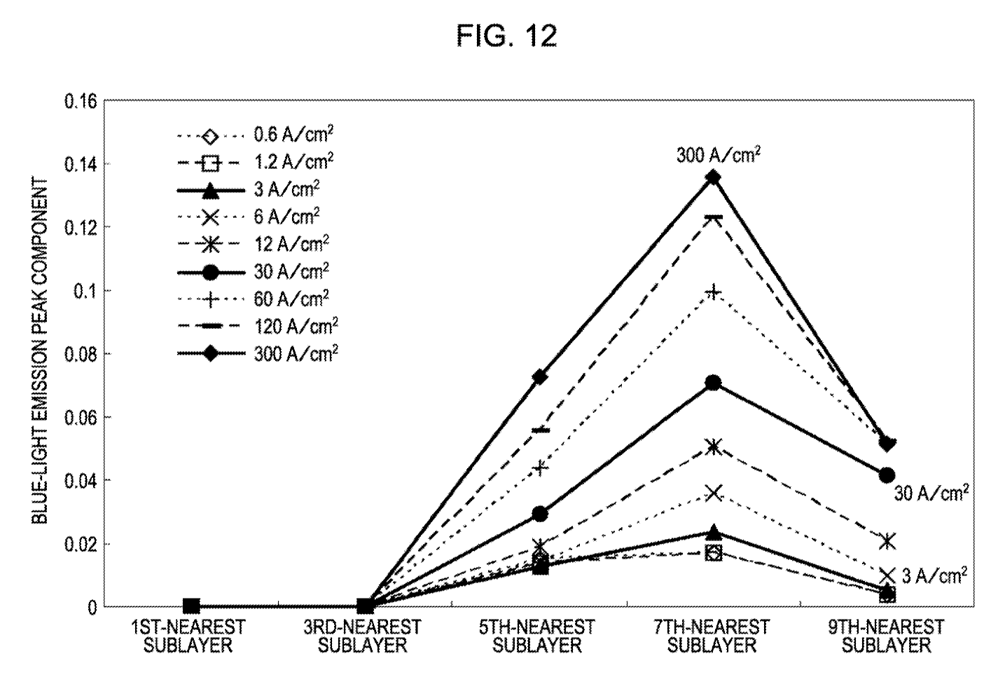

Next, additional GaN-based light-emitting diodes each having a layered structure similar to that of the GaN-based light-emitting diode of Sample 1 were prepared as in Sample 1 except that, among the nine well layers in the active layer 36, a specific single layer was composed of an In_{0.15}Ga_{0.85}N sublayer having a thickness of 3 nm. A GaN-based light-emitting diode in which a well layer which is a well layer located nearest to the n-type GaN layer 34 is composed of an In_{0.15}Ga_{0.85}N sublayer is referred to as Sample 2. A GaN-based light-emitting diode in which a well layer which is a well layer located third-nearest to the n-type GaN layer 34 is composed of an In_{0.15}Ga_{0.85}N sublayer is referred to as Sample 3. A GaN-based light-emitting diode in which a well layer which is a well layer located fifth-nearest to the n-type GaN layer 34 is composed of an In_{0.15}Ga_{0.85}N sublayer is referred to as Sample 4. A GaN-based light-emitting diode in which a well layer which is a well layer located seventh-nearest to the n-type GaN layer 34 is composed of an In_{0.15}Ga_{0.85}N sublayer is referred to as Sample 5. A GaN-based light-emitting diode in which a well layer which is a well layer located ninth-nearest to the n-type GaN layer 34 is composed of an In_{0.15}Ga_{0.85}N sublayer is referred to as Sample 6. In these GaN-based light-emitting diodes of Samples 2 to 6, other well layers were composed of In_{0.23}Ga_{0.77}N sublayers each having a thickness of 3 nm, as described above. In these GaN-based light-emitting diodes of Samples 2 to 6, the emission peak wavelength was 515 nm and the luminous efficiency was 180 mW/A at a drive current density of 60 A/cm². However, in some samples, in addition to green-light emission (emission wavelength: about 515 nm), a small emission peak due to the presence of the well layer composed of the In_{0.15}Ga_{0.85}N sublayer was also observed in the blue-light emission range (emission wavelength: about 450 nm). FIG. 12 shows the ratio of the blue-light emission peak component to the total peak component. In the horizontal axis of FIG. 12, the terms “first-nearest sublayer”, “third-nearest sublayer”, and so forth denote the positions of the well layer composed of an In_{0.15}Ga_{0.85}N sublayer relative to the n-type GaN layer 34 side. The data of the ratio of the blue-light emission peak component to the total peak component corresponding to the Nth sublayer (N=1, 3, 5, 7, or 9) shown in the horizontal axis of FIG. 12 is data of the ratio of the blue-light emission peak component to the total peak component in the GaN-based light-emitting diodes, in which a well layer located at the Nth position in the active layer 36 is composed of an In_{0.15}Ga_{0.85}N sublayer, measured at each drive current density.

As is apparent from FIG. 12, at any drive current density, light emission locally occurred in the active layer 36 with a multiquantum well structure in an area of about ⅔ the distance through the active layer 36 from the p-type GaN layer side in the thickness direction of the active layer 36. In addition, 80% of the light emission is constituted by light emitted from an area of the active layer 36, the area ranging from the boundary with the p-type GaN layer to a position halfway through the active layer 36 in the thickness direction of the active layer 36. A reason that the light emission significantly locally occurs is a difference between the mobility of electrons and the mobility of holes. In a GaN-based compound semiconductor, since the mobility of holes is small, holes reach only well layers of the active layer 36 near the p-type GaN layer. Therefore, it is believed that light emission caused by recombination of holes and electrons locally occurs in the area adjacent to the p-type GaN layer. In addition, another possible factor is as follows. From the standpoint of permeability of a heterobarrier composed of well layers and barrier layers to carriers, it is difficult for holes having a large effective mass to tunnel through a plurality of barrier layers and reach well layers of the active layer 36 disposed adjacent to the n-type GaN layer 34.

These results show that, in order to efficiently utilize the light emission that locally occurs at the p-type GaN layer side, it is effective to use a multiquantum well structure including well layers with an asymmetric distribution in which the well layers are locally disposed at the p-type GaN layer side. Furthermore, the peak of the emission distribution is located in an area that is ⅓ to ¼ the distance through the active layer 36 from the boundary with the p-type GaN layer in the thickness direction of the active layer 36.

Examples will now be described.

A GaN-based light-emitting diode in Example 1 has the same structure as the GaN-based light-emitting diode of Sample 1 except for the configuration and the structure of the active layer 36.

Table 1 shows the details of multiquantum well structures constituting an active layer 36. In Table 1 and Table 2 described below, the numbers in the parentheses at the right side of the values of the well layer thickness or the barrier layer thickness show the cumulative thickness from the boundary of the active layer 36 adjacent to the n-type GaN layer 34 (more specifically, the boundary between an undoped GaN layer and the active layer 36 in Example 1).

TABLE 1

| | | Comparative |
|---|---|---|
| | Example 1 | Example 1 |
| Total thickness of | 150 | 147 |
| light-emitting layer (tₒ nm) | | |
| | An active layer is divided | |
| | into two portions | |
| | at a position of 2tₒ/3. | |
| Thickness of first area of | 100 | 98 |
| light-emitting layer (t₁ nm) | | |
| Thickness of second area of | 50 | 49 |
| light-emitting layer (t₂ nm) | | |
| Number of well layers (WL) | 10 | The same as that to |
| | | the left. |
| Number of barrier layers | 9 | The same as that to |
| | | the left. |
| Number of well layers in first area | 6 | 6 + ⅔ |
| of light-emitting layer WL₁ | | |
| Number of well layers in second area | 4 | 3 + ⅓ |
| of light-emitting layer WL₂ | | |
| Well layer density in first area | 0.90 | 1.00 |
| of light-emitting layer d₁ | | |
| Well layer density in second area | 1.20 | 1.00 |
| of light-emitting layer d₂ | | |
| First well layer thickness (nm) | 3 (3) | 3 (3) |
| First barrier layer thickness (nm) | 25 (28) | 13 (16) |
| Second well layer thickness (nm) | 3 (31) | 3 (19) |
| Second barrier layer thickness (nm) | 25 (56) | 13 (32) |
| Third well layer thickness (nm) | 3 (59) | 3 (35) |
| Third barrier layer thickness (nm) | 10 (69) | 13 (48) |
| Fourth well layer thickness (nm) | 3 (72) | 3 (51) |
| Fourth barrier layer thickness (nm) | 10 (82) | 13 (64) |
| Fifth well layer thickness (nm) | 3 (85) | 3 (67) |
| Fifth barrier layer thickness (nm) | 10 (95) | 13 (80) |
| Sixth well layer thickness (nm) | 3 (98) | 3 (83) |
| Sixth barrier layer thickness (nm) | 10 (108) | 13 (96) |
| Seventh well layer thickness (nm) | 3 (111) | 3 (99) |
| Seventh barrier layer thickness (nm) | 10 (121) | 13 (112) |
| Eighth well layer thickness (nm) | 3 (124) | 3 (115) |
| Eighth barrier layer thickness (nm) | 10 (134) | 13 (128) |
| Ninth well layer thickness (nm) | 3 (137) | 3 (131) |
| Ninth barrier layer thickness (nm) | 10 (147) | 13 (144) |
| Tenth well layer thickness (nm) | 3 (150) | 3 (147) |

In Example 1, the total thickness of the active layer 36 is represented by t₀, the well layer density in a first area of the active layer 36 ranging from the boundary at the n-type GaN layer 34 side of the active layer 36 (more specifically, in Example 1, the boundary between the undoped GaN layer and the active layer 36) to a position corresponding to the thickness (2t₀/3) is represented by d₁, and the well layer density in a second area of the active layer 36 ranging from the boundary at the p-type AlGaN layer 38 side of the active layer 36 (more specifically, in Example 1, the boundary between the undoped GaN layer and the active layer 36) to a position corresponding to the thickness (t₀/3) is represented by d₂. In this case, the well layers in the active layer 36 are arranged so as to satisfy the relationship d₁<d₂.

More specifically, the well layer density d₁ and the well layer density d₂ are calculated as follows using formulae (1) and (2).

### EXAMPLE 1

$$\begin{matrix}{d}_{2} = ( {WL}_{2} / WL ) / ( {t}_{2} / {t}_{0} ) \\ = ( 4 / 10 ) / ( 50 / 150 ) \\ = 1.20 \\ {d}_{1} = ( {WL}_{1} / WL ) / ( {t}_{1} / {t}_{0} ) \\ = ( 6 / 10 ) / ( 100 / 150 ) \\ = 0.90\end{matrix}$$

For comparison, a GaN-based light-emitting diode including an active layer 36 shown as Comparative Example 1 in Table 1 was prepared.

In the GaN-based light-emitting diodes of Example 1 and Comparative Example 1, the area of the active layer 36 (area of the joined portion) was 6×10⁻⁴ cm². Accordingly, the drive current density of the GaN-based light-emitting diodes is calculated by dividing the drive current by 6×10⁻⁴ cm². For example, when a drive current of 20 mA is supplied, the drive current density is 33 A/cm².

The well layer density d₁ and the well layer density d₂ in Comparative Example 1 are calculated as follows using formulae (1) and (2).

### COMPARATIVE EXAMPLE 1

$$\begin{matrix}{d}_{2} = ( {WL}_{2} / WL ) / ( {t}_{2} / {t}_{0} ) \\ = \{ ( 3 + 1 / 3 ) / 10 \} / ( 49 / 147 ) \\ = 1.00 \\ {d}_{1} = ( {WL}_{1} / WL ) / ( {t}_{1} / {t}_{0} ) \\ = \{ ( 6 + 2 / 3 ) / 10 \} / ( 98 / 147 ) \\ = 1.00\end{matrix}$$

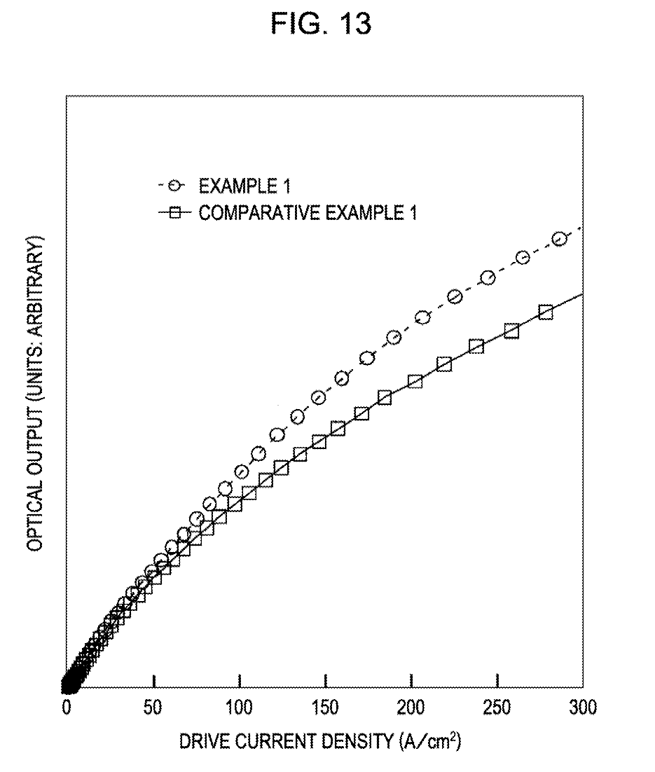

FIG. 13 shows measurement results of the relationship between the drive current density and the optical output of the GaN-based light-emitting diodes. The optical output of the GaN-based light-emitting diode of Example 1 was increased, as compared with that of Comparative Example 1. The difference between the optical output of the GaN-based light-emitting diode of Example 1 and the optical output of the GaN-based light-emitting diode of Comparative Example 1 became significant at a drive current density of 50 A/cm² or more. The difference was 10 percent or more at a drive current density of 100 A/cm² or more. That is, the difference between the optical output of the GaN-based light-emitting diode of Example 1 and the optical output of the GaN-based light-emitting diode of Comparative Example 1 was markedly increased at a drive current density of 50 A/cm² or more, preferably 100 A/cm² or more. Consequently, the GaN-based light-emitting diode of Example 1 is preferably used at a drive current density of 50 A/cm² or more, preferably 100 A/cm² or more.

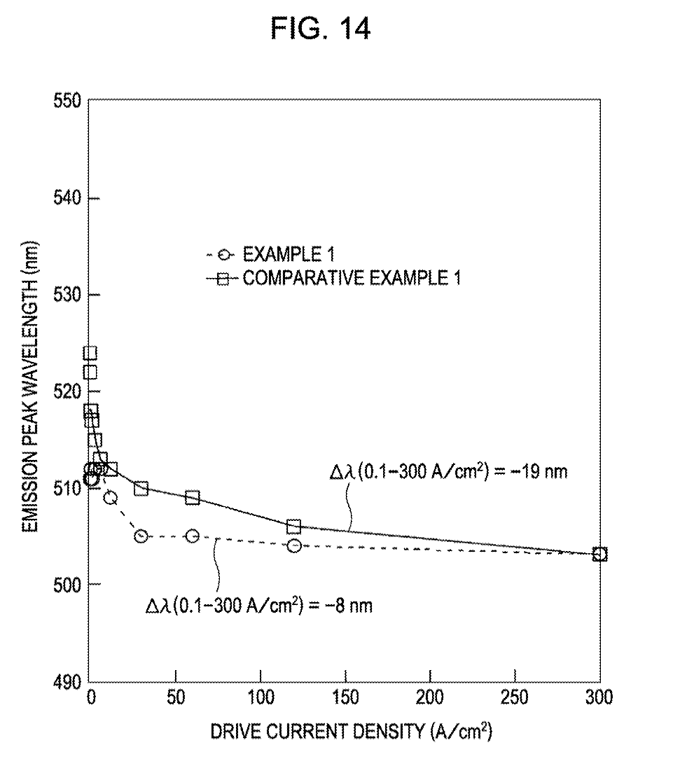

FIG. 14 shows the relationship between the drive current density and the emission peak wavelength of the GaN-based light-emitting diodes. When the drive current density was increased from 0.1 A/cm² to 300 A/cm², Δλ in Comparative Example 1 was −19 nm, and in contrast, Δλ in Example 1 was −8 nm, thus realizing a small emission wavelength shift. In particular, in Example 1, an emission-wavelength shift was hardly observed at a drive current density of 30 A/cm² or more. That is, since the shift in the emission wavelength is very small at a drive current density of 30 A/cm² or more, this GaN-based light-emitting diode of Example 1 is preferable from the standpoint of the control of the emission wavelength and the luminescent color. The wavelength shift in the GaN-based light-emitting diode of Example 1 was markedly smaller than that of Comparative Example 1 particularly at a drive current density of 50 A/cm² or more, or 100 A/cm² or more. Thus, the GaN-based light-emitting diode of Example 1 was superior to that of Comparative Example 1.

The method of controlling the intensity of emission (luminance) of a GaN-based light-emitting diode is not particularly limited. The intensity of emission (luminance) may be controlled by adjusting a peak current of the drive current. Alternatively, the intensity of emission (luminance) may be controlled by adjusting the pulse width of the drive current or by the pulse density of the drive current. These methods may be used in combination.

When the total thickness of the active layer 36 is represented by to, the well layer density in a first area of the active layer 36 ranging from the boundary at the n-type GaN layer 34 side of the active layer 36 (more specifically, the boundary between the undoped GaN layer and the active layer 36) to a position corresponding to the thickness (t₀/2) is represented by d₁, the well layer density in a second area of the active layer 36 ranging from the boundary at the p-type AlGaN layer 38 side of the active layer 36 (more specifically, the boundary between the undoped GaN layer and the active layer 36) to a position corresponding to the thickness (t₀/2) is represented by d₂, and the well layers in the active layer 36 are arranged so as to satisfy the relationship d₁<d₂, the well layer density d₁ and the well layer density d₂ are calculated as follows using formulae (1) and (2).

<Densities Corresponding to Example 1>

$$\begin{matrix}{d}_{2} = ( {WL}_{2} / WL ) / ( {t}_{2} / {t}_{0} ) \\ = ( 6 / 10 ) / ( 75 / 150 ) \\ = 1.20 \\ {d}_{1} = ( {WL}_{1} / WL ) / ( {t}_{1} / {t}_{0} ) \\ = ( 4 / 10 ) / ( 75 / 150 ) \\ = 0.80\end{matrix}$$

<Densities corresponding to Comparative Example 1>

$$\begin{matrix}{d}_{2} = ( {WL}_{2} / WL ) / ( {t}_{2} / {t}_{0} ) \\ = ( 5 / 10 ) / \{ ( 73 + 1 / 2 ) / 147 \} \\ = 1.00 \\ {d}_{1} = ( {WL}_{1} / WL ) / ( {t}_{1} / {t}_{0} ) \\ = ( 5 / 10 ) / \{ ( 73 + 1 / 2 ) / 147 \} \\ = 1.00\end{matrix}$$

Furthermore, when the total thickness of the active layer 36 is represented by t₀, the well layer density in a first area of the active layer 36 ranging from the boundary at the n-type GaN layer 34 side of the active layer 36 (more specifically, the boundary between the undoped GaN layer and the active layer 36) to a position corresponding to the thickness (t₀/3) is represented by d₁, the well layer density in a second area of the active layer 36 ranging from the boundary at the p-type AlGaN layer 38 side of the active layer 36 (more specifically, the boundary between the undoped GaN layer and the active layer 36) to a position corresponding to the thickness (2t₀/3) is represented by d₂, and the well layers in the active layer 36 are arranged so as to satisfy the relationship d₁<d₂, the well layer density d₁ and the well layer density d₂ are calculated as follows using formulae (1) and (2).

<Densities Corresponding to Example 1>

$$\begin{matrix}{d}_{2} = ( {WL}_{2} / WL ) / ( {t}_{2} / {t}_{0} ) \\ = ( 8 / 10 ) / ( 100 / 150 ) \\ = 1.20 \\ {d}_{1} = ( {WL}_{1} / WL ) / ( {t}_{1} / {t}_{0} ) \\ = ( 2 / 10 ) / ( 50 / 150 ) \\ = 0.60\end{matrix}$$

<Densities Corresponding to Comparative Example 1>

$$\begin{matrix}{d}_{2} = ( {WL}_{2} / WL ) / ( {t}_{2} / {t}_{0} ) \\ = \{ ( 6 + 2 / 3 ) / 10 \} / ( 98 / 147 ) \\ = 1.00 \\ {d}_{1} = ( {WL}_{1} / WL ) / ( {t}_{1} / {t}_{0} ) \\ = \{ ( 3 + 1 / 3 ) / 10 \} / ( 49 / 147 ) \\ = 1.00\end{matrix}$$

As described above, in any case corresponding to Example 1, the well layers in the active layer 36 are arranged so as to satisfy the relationship d₁<d₂.

Example 2 will now be described. Example 2 is a modification of Example 1. In a GaN-based light-emitting diode of Example 2, the emission wavelength was controlled to about 445 nm by adjusting the In content ratio of well layers in an active layer 36. Table 2 shows the detail of the multiquantum well structure constituting the active layer 36 in the GaN-based light-emitting diode of Example 2.

TABLE 2

| | | Comparative |
|---|---|---|
| | Example 2 | Example 2 |
| Total thickness of | 122 | 124.5 |
| light-emitting layer (tₒ nm) | | |
| | An active layer is divided | |
| | into two portions | |
| | at a position of 2tₒ/3. | |
| Thickness of first area of | 81 + ⅓ | 83 |
| light-emitting layer (t₁ nm) | | |
| Thickness of second area of | 40 + ⅔ | 41 + ½ |
| light-emitting layer (t₂ nm) | | |
| Number of well layers (WL) | 10 | The same as that to |
| | | the left. |
| Number of barrier layers | 9 | The same as that to |
| | | the left. |
| Number of well layers in first area | 4 + 7/9 | 6 + ⅔ |
| of light-emitting layer WL₁ | | |
| Number of well layers in second area | 5 + 2/9 | 3 + ⅓ |
| of light-emitting layer WL₂ | | |
| Well layer density in first area of | 0.72 | 1.00 |
| light-emitting layer d₁ | | |
| Well layer density in second area | 1.57 | 1.00 |
| of light-emitting layer d₂ | | |
| First well layer thickness (nm) | 3 (3) | 3 (3) |
| First barrier layer thickness (nm) | 52 (55) | 10.5 (13.5) |
| Second well layer thickness (nm) | 3 (58) | 3 (16.5) |
| Second barrier layer thickness (nm) | 5 (63) | 10.5 (27) |
| Third well layer thickness (nm) | 3 (66) | 3 (30) |
| Third barrier layer thickness (nm) | 5 (71) | 10.5 (40.5) |
| Fourth well layer thickness (nm) | 3 (74) | 3 (43.5) |
| Fourth barrier layer thickness (nm) | 5 (79) | 10.5 (54) |
| Fifth well layer thickness (nm) | 3 (82) | 3 (57) |
| Fifth barrier layer thickness (nm) | 5 (87) | 10.5 (67.5) |
| Sixth well layer thickness (nm) | 3 (90) | 3 (70.5) |
| Sixth barrier layer thickness (nm) | 5 (95) | 10.5 (81) |
| Seventh well layer thickness (nm) | 3 (98) | 3 (84) |
| Seventh barrier layer thickness (nm) | 5 (103) | 10.5 (94.5) |
| Eighth well layer thickness (nm) | 3 (106) | 3 (97.5) |
| Eighth barrier layer thickness (nm) | 5 (111) | 10.5 (108) |
| Ninth well layer thickness (nm) | 3 (114) | 3 (111) |
| Ninth barrier layer thickness (nm) | 5 (119) | 10.5 (121.5) |
| Tenth well layer thickness (nm) | 3 (122) | 3 (124.5) |

The well layer density d₁ and the well layer density d₂ are calculated as follows using formulae (1) and (2).

### EXAMPLE 2

$$\begin{matrix}{d}_{2} = ( {WL}_{2} / WL ) / ( {t}_{2} / {t}_{0} ) \\ = \{ ( 5 + 2 / 9 ) / 10 \} / \{ ( 40 + 2 / 3 ) / 122 \} \\ = 1.57 \\ {d}_{1} = ( {WL}_{1} / WL ) / ( {t}_{1} / {t}_{0} ) \\ = \{ ( 4 + 7 / 9 ) / 10 \} / \{ ( 81 + 1 / 3 ) / 122 \} \\ = 0.72\end{matrix}$$

For comparison, a GaN-based light-emitting diode including an active layer 36 shown as Comparative Example 2 in Table 2 was prepared. The well layer density d₁ and the well layer density d₂ in Comparative Example 2 are calculated as follows using formulae (1) and (2).

### COMPARATIVE EXAMPLE 2

$$\begin{matrix}{d}_{2} = ( {WL}_{2} / WL ) / ( {t}_{2} / {t}_{0} ) \\ = \{ ( 3 + 1 / 3 ) / 10 \} / \{ ( 41 + 1 / 2 ) / ( 124 + 1 / 2 ) \} \\ = 1.00 \\ {d}_{1} = ( {WL}_{1} / WL ) / ( {t}_{1} / {t}_{0} ) \\ = \{ ( 6 + 2 / 3 ) / 10 \} / \{ 83 / ( 124 + 1 / 2 ) \} \\ = 1.00\end{matrix}$$

The GaN-based light-emitting diodes of Example 2 and Comparative Example 2 were evaluated by the same method as described in Example 1.

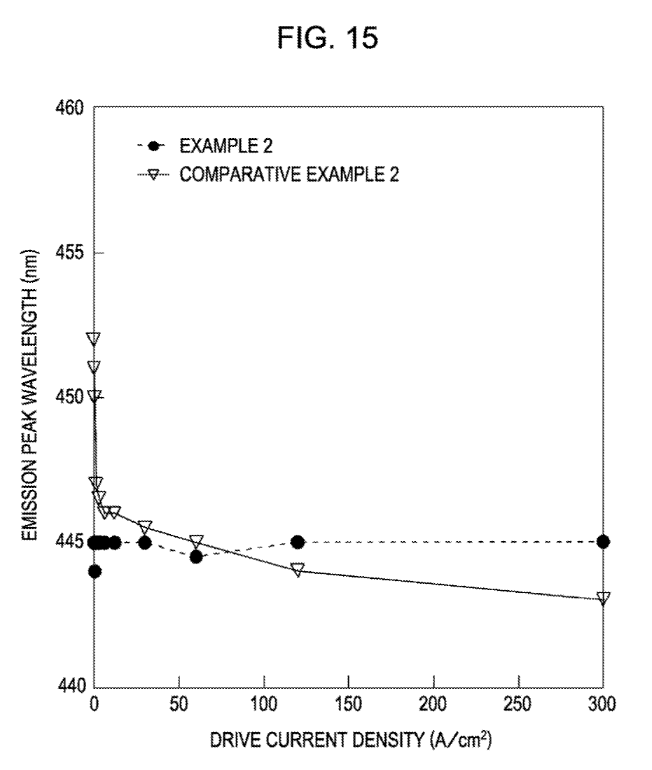

FIG. 15 shows the relationship between the drive current density and the emission peak wavelength of the GaN-based light-emitting diodes. When the drive current density was increased from 0.1 A/cm² to 300 A/cm², Δλ in Comparative Example 2 was −9 nm, and in contrast, Δλ in Example 2 was −1 nm, thus realizing an extremely small emission wavelength shift. The wavelength shift in the GaN-based light-emitting diode of Example 2 that emits blue light was markedly smaller than that in the GaN-based light-emitting diode of Comparative Example 2. Thus, the GaN-based light-emitting diode of Example 2 was superior to that of Comparative Example 2.

According to the second embodiment, the same advantages as those in the first embodiment can be realized. In addition, the GaN-based light-emitting diode of the second embodiment is advantageous in that a large shift in the emission wavelength due to an increase in the drive current density can be suppressed, and the luminance can be controlled over a wider range.

A third embodiment will now be described. In the third embodiment, a description will be made of a transmissive liquid crystal display including a light-emitting diode backlight having the GaN-based light-emitting diode of the first embodiment as a white light source.

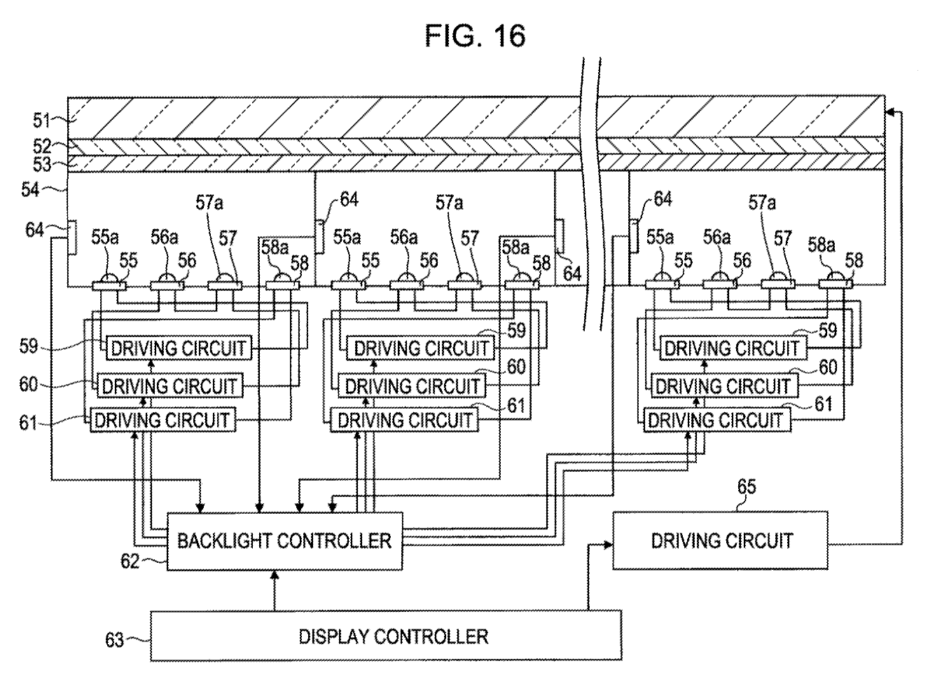

FIG. 16 is a transmissive liquid crystal display according to the third embodiment.

As shown in FIG. 16, in this transmissive liquid crystal display, a prism plate 52 is provided on the back surface of a liquid crystal panel 51, a diffusion plate 53 is provided on the prism plate 52, and a light-emitting diode backlight 54 is provided on the diffusion plate 53.

In the light-emitting diode backlight 54, cells each composed of a red-light-emitting diode 55, two green-light-emitting diodes 56 and 57, and a blue-light-emitting diode 58 are arranged in a matrix shape. The number of cells in the vertical direction and the number of cells in the horizontal direction are selected according to need. Convex lenses 55a, 56a, 57a, and 58a are provided on the red-light-emitting diode 55, the green-light-emitting diodes 56 and 57, and the blue-light-emitting diode 58, respectively. Alternatively, instead of using the convex lenses 55a, 56a, 57a, and 58a, concave lenses or lenses each having another complex shape may be used in accordance with the use, the optical design, and the like. Among red-light-emitting diodes 55, green-light-emitting diodes 56 and 57, and blue-light-emitting diodes 58, at least either red-light-emitting diodes 55, green-light-emitting diodes 56 and 57, or blue-light-emitting diodes 58, preferably, the green-light-emitting diodes 56 and 57, and the blue-light-emitting diodes 58 are composed of the GaN-based light-emitting diode according to the first embodiment. For example, AlGaInP-based light-emitting diodes may be used as the red-light-emitting diodes 55, and the GaN-based light-emitting diodes according to the first embodiment may be used as at least either the green-light-emitting diodes 56 and 57, or the blue-light-emitting diodes 58. Each of the red-light-emitting diodes 55 is driven by a driving circuit 59, each of the green-light-emitting diodes 56 and 57 is driven by a driving circuit 60, and each of the blue-light-emitting diodes 58 is driven by a driving circuit 61. The driving circuits 59, 60, and 61 of each cell are controlled by a backlight controller 62, and this backlight controller 62 is controlled by a display controller 63. An optical sensor 64 is provided in each of the cells. The emission intensities of the red-light-emitting diodes 55, the green-light-emitting diodes 56 and 57, and the blue-light-emitting diodes 58 are detected by the optical sensors 64. The outputs from these optical sensors 64 are input to the backlight controller 62.

The liquid crystal panel 51 is driven by a driving circuit 65, and this driving circuit 65 is controlled by the display controller 63.

In this case, regarding the luminance modulation of the red-light-emitting diodes 55, the green-light-emitting diodes 56 and 57, and the blue-light-emitting diodes 58, modulation of a part of or all of the intensity of light emission may be performed by a driving current amplitude modulation, by combining a current pulse width modulation with a current amplitude modulation, or by combining a current density modulation with a current amplitude modulation.

According to the third embodiment, when GaN-based light-emitting diodes are used as the red-light-emitting diodes 55, the green-light-emitting diodes 56 and 57, and the blue-light-emitting diodes 58 constituting each cell of the light-emitting diode backlight 54, the luminous efficiencies of the GaN-based light-emitting diodes can be increased. Consequently, the luminance of the light-emitting diode backlight 54 can be increased, and thus a transmissive liquid crystal display with a high luminance can be obtained.

A fourth embodiment will now be described. In this fourth embodiment, a description will be made of a projection display including a red-light-emitting diode light source, a green-light-emitting diode light source, a blue-light-emitting diode light source, and a light valve element composed of a transmissive liquid crystal panel.

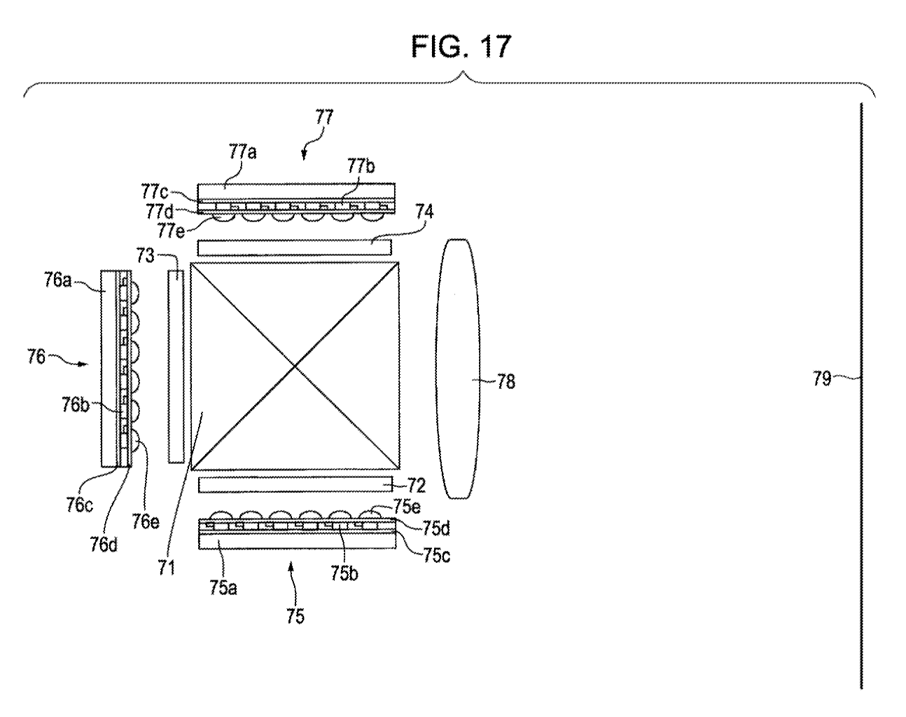

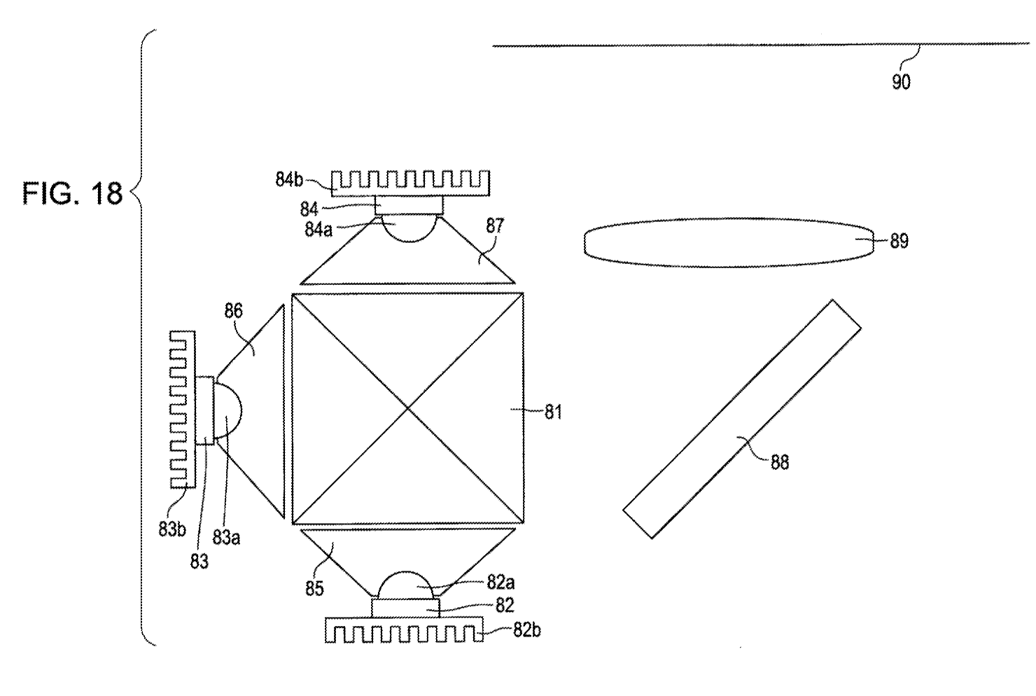

FIG. 17 shows a projection display according to the fourth embodiment.

As shown in FIG. 17, in this projection display, high-temperature polycrystalline silicon thin-film transistor (TFT) liquid crystal panels 72, 73, and 74 are provided near three surfaces of a dichroic prism 71 orthogonal to each other. A red-light-emitting diode panel 75 is provided at the back side of the high-temperature polycrystalline silicon TFT liquid crystal panel 72, a green-light-emitting diode panel 76 is provided at the back side of the high-temperature polycrystalline silicon TFT liquid crystal panel 73, and a blue-light-emitting diode panel 77 is provided at the back side of the high-temperature polycrystalline silicon TFT liquid crystal panel 74. A projection lens 78 is provided so as to face the remaining surface of the dichroic prism 71.

In the red-light-emitting diode panel 75, red-light-emitting diodes 75b are arranged on a substrate 75a in a matrix shape. The number of light-emitting diodes 75b in the vertical direction and the number of light-emitting diodes 75b in the horizontal direction are selected according to need. For example, AlGaInP-based light-emitting diodes are used as the light-emitting diodes 75b. A surface of each of the light-emitting diodes 75b adjacent to a p-type layer is connected to a wiring electrode 75c. Another surface of each of the light-emitting diodes 75b adjacent to an n-type layer is connected to a transparent electrode 75d. Convex lenses 75e are provided on the transparent electrode 75d at positions corresponding to each of the light-emitting diodes 75b. In the green-light-emitting diode panel 76, green-light-emitting diodes 76b are arranged on a substrate 76a in a matrix shape. The number of light-emitting diodes 76b in the vertical direction and the number of light-emitting diodes 76b in the horizontal direction are selected according to need. The GaN-based light-emitting diodes according to the first embodiment are used as the light-emitting diodes 76b. A surface of each of the light-emitting diodes 76b adjacent to a p-type layer is connected to a wiring electrode 76c. Another surface of each of the light-emitting diodes 76b adjacent to an n-type layer is connected to a transparent electrode 76d. Convex lenses 76e are provided on the transparent electrode 76d at positions corresponding to each of the light-emitting diodes 76b. In the blue-light-emitting diode panel 77, blue-light-emitting diodes 77b are arranged on a substrate 77a in a matrix shape. The number of light-emitting diodes 77b in the vertical direction and the number of light-emitting diodes 77b in the horizontal direction are selected according to need. The GaN-based light-emitting diodes according to the first embodiment are used as the light-emitting diodes 77b. A surface of each of the light-emitting diodes 77b adjacent to a p-type layer is connected to a wiring electrode 77c. Another surface of each of the light-emitting diodes 77b adjacent to an n-type layer is connected to a transparent electrode 77d. Convex lenses 77e are provided on the transparent electrode 77d at positions corresponding to each of the light-emitting diodes 77b.

In this projection display, transmission of red light emitted from the red-light-emitting diode panel 75, transmission of green light emitted from the green-light-emitting diode panel 76, and transmission of blue light emitted from the blue-light-emitting diode panel 77 are controlled by the high-temperature polycrystalline silicon TFT liquid crystal panels 72, 73, and 74, respectively. The red light, the green light, and the blue light are combined in the dichroic prism 71 to produce an image. The image is projected onto a screen 79 via the projection lens 78.

In this case, the luminance modulation of the red-light-emitting diodes 75b, the green-light-emitting diodes 76b, and the blue-light-emitting diodes 77b is performed by the same method as described in the third embodiment.

According to the fourth embodiment, a projection display having a high luminance can be obtained.

A fifth embodiment will now be described. In this fifth embodiment, a description will be made of a projection display including a red-light-emitting diode light source, a green-light-emitting diode light source, a blue-light-emitting diode light source, and a light valve element composed of a digital micro-mirror display (DMD).

FIG. 18 shows the projection display according to the fifth embodiment.

As shown in FIG. 18, in this projection display, a red power light-emitting diode 82, a green power light-emitting diode 83, and a blue power light-emitting diode 84 are provided so as to face three surfaces of a dichroic prism 81 orthogonal to each other. For example, an AlGaInP-based light-emitting diode is used as the red power light-emitting diode 82. The GaN-based light-emitting diode according to the first embodiment is used as at least one of the green power light-emitting diode 83 and the blue power light-emitting diode 84. A convex lens 82a is provided on the red power light-emitting diode 82, and a radiation fin 82b is provided on the reverse surface of the red power light-emitting diode 82. Light emitted from the power light-emitting diode 82 passes through the convex lens 82a and is then projected onto a surface of the dichroic prism 81 with a light-guiding member 85. A convex lens 83a is provided on the green power light-emitting diode 83, and a radiation fin 83b is provided on the reverse surface of the green power light-emitting diode 83. Light emitted from the power light-emitting diode 83 passes through the convex lens 83a and is then projected onto a surface of the dichroic prism 81 with a light-guiding member 86. A convex lens 84a is provided on the blue power light-emitting diode 84, and a radiation fin 84b is provided on the reverse surface of the blue power light-emitting diode 84. Light emitted from the power light-emitting diode 84 passes through the convex lens 84a and is then projected onto a surface of the dichroic prism 81 with a light-guiding member 87.

A DMD 88 is provided so as to face the remaining surface of the dichroic prism 81. The red light emitted from the red power light-emitting diode 82, the green light emitted from the green power light-emitting diode 83, and the blue light emitted from the blue power light-emitting diode 84 are mixed in the dichroic prism 81 to form white light. The white light enters the DMD 88 to produce an image. The image is projected onto a screen 90 via a projection lens 89.

In this case, the luminance modulation of the red power light-emitting diodes 82, the green power light-emitting diodes 83, and the blue power light-emitting diodes 84 is performed by the same method as described in the third embodiment.

According to the fifth embodiment, a projection display having a high luminance can be obtained.

A sixth embodiment will now be described.

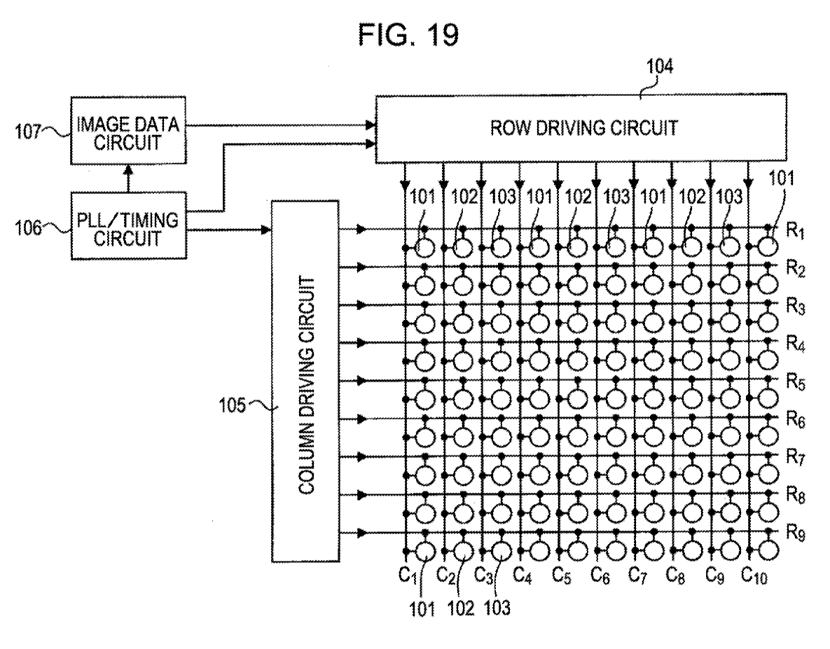

FIG. 19 shows a passive-matrix light-emitting diode display according to the sixth embodiment.

As shown in FIG. 19, in this light-emitting diode display, pixels each composed of a red-light-emitting diode 101, a green-light-emitting diode 102, and a blue-light-emitting diode 103 are arranged in a matrix shape. AlGaInP-based light-emitting diodes are used as the red-light-emitting diodes 101, and the GaN-based light-emitting diodes according to the first embodiment are used as at least one of the green-light-emitting diodes 102 and the blue-light-emitting diodes 103. The number of pixels in the vertical direction and the number of pixels in the horizontal direction are selected according to need. Row selection lines (address lines) C₁, C₂, . . . , C₁₀, and the like are connected to a row driving circuit 104. Column selection lines (signal lines) R₁, R₂, . . . , R₉, and the like are connected to a column driving circuit 105. The row driving circuit 104 and the column driving circuit 105 are controlled by a phase-locked loop (PLL)/timing circuit 106 to select a pixel, and an RGB signal is supplied from an image data circuit 107 to the row driving circuit 104. In response to the RGB signal, current is supplied to the red-light-emitting diode 101, the green-light-emitting diode 102, and the blue-light-emitting diode 103 of the selected pixel to drive the light-emitting diode display. A dot sequential scanning system, a line sequential scanning system, or the like can be used as the driving scanning system.

In this case, the luminance modulation of the red-light-emitting diodes 101, the green light-emitting diodes 102, and the blue light-emitting diodes 103 is performed by the same method as described in the third embodiment.

According to the sixth embodiment, a light-emitting diode display having a high luminance can be obtained.

A seventh embodiment will now be described.

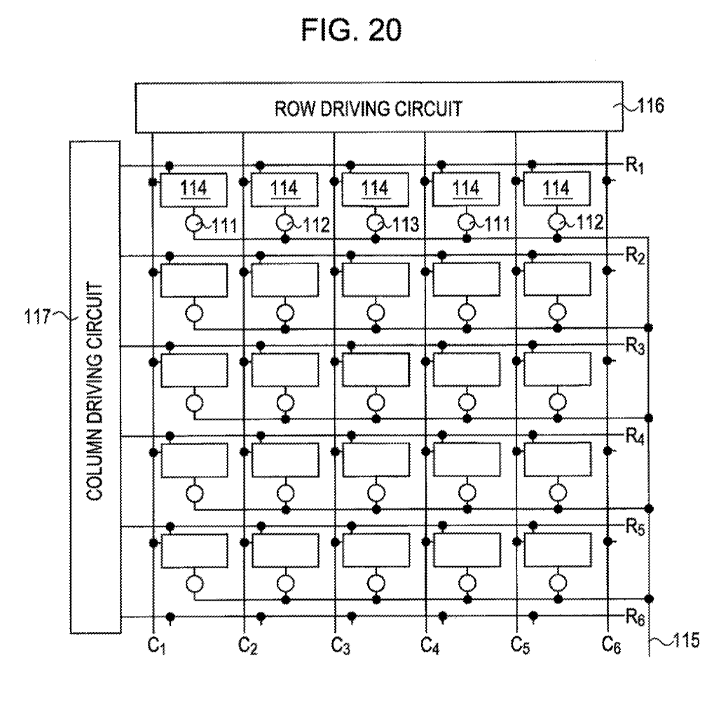

FIG. 20 shows an active-matrix light-emitting diode display according to the seventh embodiment.

As shown in FIG. 20, in this light-emitting diode display, pixels each composed of a red-light-emitting diode 111, a green-light-emitting diode 112, a blue-light-emitting diode 113, and an active element 114 are arranged in a matrix shape. AlGaInP-based light-emitting diodes are used as the red-light-emitting diodes 111, and the GaN-based light-emitting diodes according to the first embodiment are used as at least one of the green-light-emitting diodes 112 and the blue-light-emitting diodes 113. The number of pixels in the vertical direction and the number of pixels in the horizontal direction are selected according to need. A surface of each of the red-light-emitting diodes 111, the green-light-emitting diodes 112, and the blue-light-emitting diodes 113 adjacent to an n-type layer is connected to a ground wire 115, and another surface thereof adjacent to a p-type layer is connected to the corresponding active element 114. The active elements 114 are elements that can drive the red-light-emitting diodes 111, the green-light-emitting diodes 112, and the blue-light-emitting diodes 113 and composed of, for example, silicon integrated circuits. Row selection lines (address lines) C₁, C₂, . . . , C₆, and the like are connected to a row driving circuit 116. Column selection lines (signal lines) R₁, R₂, . . . , R₆, and the like are connected to a column driving circuit 117. An active element 114 of a pixel selected by the row driving circuit 116 and the column driving circuit 117 is driven. Consequently, current is supplied to the red-light-emitting diode 111, the green-light-emitting diode 112, and the blue-light-emitting diode 113 of the selected pixel to drive the light-emitting diode display.

In this case, the luminance modulation of the red-light-emitting diodes 111, the green light-emitting diodes 112, and the blue light-emitting diodes 113 is performed by the same method as described in the third embodiment.

According to the seventh embodiment, a light-emitting diode display having a high luminance can be obtained.

The present application has been described according to various embodiments, where suitable modifications thereof are contemplated.

For example, the numerical values, the materials, the structures, the shapes, the substrates, the raw materials, the processes, the circuit configurations, and the like described in the first to seventh embodiments are given as examples only. For example, numerical values, materials, structures, shapes, substrates, raw materials, processes, and circuit configurations that are different from those in the above embodiments may be used according to need.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A semiconductor light-emitting element comprising:
a nitride-based Group III-V compound semiconductor,
wherein the semiconductor light-emitting element has a structure in which an active layer including one or a plurality of well layers is sandwiched between a p-side cladding layer and an n-side cladding layer, and
the composition of at least one of the well layers of the active layer is modulated in the direction perpendicular to the thickness direction of the least one of the well layers.

2. The semiconductor light-emitting element according to claim 1, wherein the composition of the at least one of the well layers is modulated such that the band gap energy of the at least one of the well layers increases or decreases in the direction from the n-side cladding layer to the p-side cladding layer.

3. The semiconductor light-emitting element according to claim 1, wherein the one or the plurality of well layers comprise a nitride-based Group III-V compound semiconductor containing indium.

4. The semiconductor light-emitting element according to claim 1, wherein the semiconductor light-emitting element is a light-emitting diode or a laser diode.

5. A method of producing a semiconductor light-emitting element including a nitride-based Group III-V compound semiconductor and having a structure in which an active layer including one or a plurality of well layers is sandwiched between a p-side cladding layer and an n-side cladding layer, the method comprising:
modulating the composition of at least one of the well layers in the direction perpendicular to the thickness direction of the at least one of the well layers during the growth of the active layer.

6. The method of producing a semiconductor light-emitting element according to claim 5, wherein the composition of the at least one of the well layers is modulated by modulating a growth condition of the at least one of the well layers during the growth thereof.

7. The method of producing a semiconductor light-emitting element according to claim 5, wherein the composition of the at least one of the well layers is modulated by modulating the growth temperature of the at least one of the well layers during the growth thereof.

8. The method of producing a semiconductor light-emitting element according to claim 5, wherein the maximum growth temperature T (° C.) after the growth of the active layer satisfies the relationship T<1,350−0.75λ when the emission wavelength is represented by λ (nm).

9. The method of producing a semiconductor light-emitting element according to claim 5, wherein the maximum growth temperature T (° C.) after the growth of the active layer satisfies the relationship T<1,250−0.75λ when the emission wavelength is represented by λ (nm).

10. A backlight comprising a plurality of semiconductor red-light-emitting elements, a plurality of semiconductor green-light-emitting elements, and a plurality of semiconductor blue-light-emitting elements,
wherein at least one of the semiconductor red-light-emitting elements, the semiconductor green-light-emitting elements, and the semiconductor blue-light-emitting elements includes a nitride-based Group III-V compound semiconductor and has a structure in which an active layer including one or a plurality of well layers is sandwiched between a p-side cladding layer and an n-side cladding layer, and the composition of at least one of the well layers of the active layer is modulated in the direction perpendicular to the thickness direction of the at least one of the well layers.

11. A display unit comprising a plurality of semiconductor red-light-emitting elements, a plurality of semiconductor green-light-emitting elements, and a plurality of semiconductor blue-light-emitting elements are arranged,
wherein at least one of the semiconductor red-light-emitting elements, the semiconductor green-light-emitting elements, and the semiconductor blue-light-emitting elements includes a nitride-based Group III-V compound semiconductor and has a structure in which an active layer including one or a plurality of well layers is sandwiched between a p-side cladding layer and an n-side cladding layer, and
the composition of at least one of the well layers of the active layer is modulated in the direction perpendicular to the thickness direction of the at least one of the well layers.

12. An electronic device comprising:
one or a plurality of semiconductor light-emitting elements,
wherein at least one of the semiconductor light-emitting elements includes a nitride-based Group III-V compound semiconductor and has a structure in which an active layer including one or a plurality of well layers is sandwiched between a p-side cladding layer and an n-side cladding layer, and
the composition of at least one of the well layers of the active layer is modulated in the direction perpendicular to the thickness direction of the at least one of the well layers.

13. A light-emitting unit comprising:
one or a plurality of semiconductor light-emitting elements and at least one color conversion material on which light emitted from the one or the plurality of the semiconductor light-emitting elements is incident,
wherein at least one of the semiconductor light-emitting elements includes a nitride-based Group III-V compound semiconductor and has a structure in which an active layer including one or a plurality of well layers is sandwiched between a p-side cladding layer and an n-side cladding layer, and
the composition of at least one of the well layers of the active layer is modulated in the direction perpendicular to the thickness direction of the at least one of the well layers.
